(19) United States
(12) Patent Application Publication
(10) Pub. No.: US 2025/0344457 A1
(43) Pub. Date: Nov. 6, 2025

(54) SEMICONDUCTOR SOURCE/DRAIN REGIONS AND METHODS OF FORMING THE SAME

(71) Applicant: Taiwan Semiconductor Manufacturing Co., Ltd.., Hsinchu (TW)

(72) Inventors: Chien Ning Yao, Hsinchu (TW); Chia-Cheng Tsai, Hsinchu (TW); Jung-Hung Chang, Yuanlin City (TW); Yu-Xuan Huang, Hsinchu (TW); Hou-Yu Chen, Zhubei City (TW); Kuo-Cheng Chiang, Zhubei City (TW); Chih-Hao Wang, Baoshan Township (TW)

(21) Appl. No.: 19/268,770

(22) Filed: Jul. 14, 2025

Related U.S. Application Data
(63) Continuation of application No. 18/643,436, filed on Apr. 23, 2024.
(60) Provisional application No. 63/550,639, filed on Feb. 7, 2024.

(51) Int. Cl. H10D 30/69; H10D 30/01; H10D 30/43; H10D 30/67; H10D 62/10; H10D 64/01

(52) U.S. Cl. CPC H10D 30/797; H10D 30/014; H10D 30/43; H10D 30/6735; H10D 30/6757; H10D 62/121; H10D 64/018

(57) ABSTRACT

A device includes a stack of first nanostructures; a first insulating layer adjacent to the stack of first nanostructures; a first source/drain region over the first insulating layer, wherein the first source/drain region includes a first semiconductor layer extending continuously over the sidewalls of the first nanostructures, wherein the first semiconductor layer is a first semiconductor material and a second semiconductor layer on the first semiconductor layer, wherein the second semiconductor layer is a second semiconductor material different from the first semiconductor material.

### PRIORITY CLAIM AND CROSS-REFERENCE

This application is a continuation of U.S. patent application Ser. No. 18/643,436, filed on Apr. 23, 2024, which claims the benefit of U.S. Provisional Application No. 63/550,639, filed on Feb. 7, 2024, each application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nanostructure-FET) in a three-dimensional view, in accordance with some embodiments.

FIGS. 2, 3, 4, 5, 6, 7, 8A, 8B, 8C, 9A, 9B, 9C, 10, 11A, 11B, 11C, 12A, 12B, 12C, 13A, 13B, 13C, 14A, 14B, 14C, 15A, 15B, 15C, 16A, 16B, and 16C are views of intermediate stages in the manufacturing of nanostructure-FETs, in accordance with some embodiments.

FIG. 17 illustrates a portion of an n-type region with strain layers, in accordance with some embodiments.

FIG. 18 illustrates a portion of an n-type region, in accordance with some embodiments.

FIGS. 19A and 19B illustrate portions of n-type regions with strain layers, in accordance with some embodiments.

FIGS. 20A, 20B, 20C, 21A, 21B, 21C, 22A, 22B, 22C, 23A, 23B, 23C, 24A, 24B, 24C, 25A, 25B, 25C, 26A, 26B, and 26C are views of intermediate stages in the manufacturing of nanostructure-FETs, in accordance with some embodiments.

FIGS. 27 and 28 are views of intermediate stages in the manufacturing of nanostructure-FETs, in accordance with some embodiments.

FIG. 29 illustrates a portion of an n-type region with strain regions, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, the epitaxial source/drain regions of n-type nanostructure-FETs include strain layers over the channel regions. The strain layers may be continuous layers of semiconductor material that extend over the sidewalls of multiple channel regions. The strain layers can increase the tensile strain of the channel regions, which can improve performance of the n-type nanostructure-FETs. Additionally, the strain layers can reduce the diffusion of impurities into nanostructures during manufacturing. For example, a strain layer comprising germanium can reduce diffusion of phosphorus from another epitaxial source/drain layer into the nanostructures. This can reduce undesirable process or performance issues due to impurity diffusion.

Embodiments are described below in a particular context, a die comprising nanostructure field-effect transistors (e.g., “nanostructure-FETs”). Various embodiments may be applied, however, to dies comprising other types of transistors (e.g., fin field-effect transistors (FinFETs), planar transistors, or the like) in lieu of or in combination with the nanostructure-FETs.

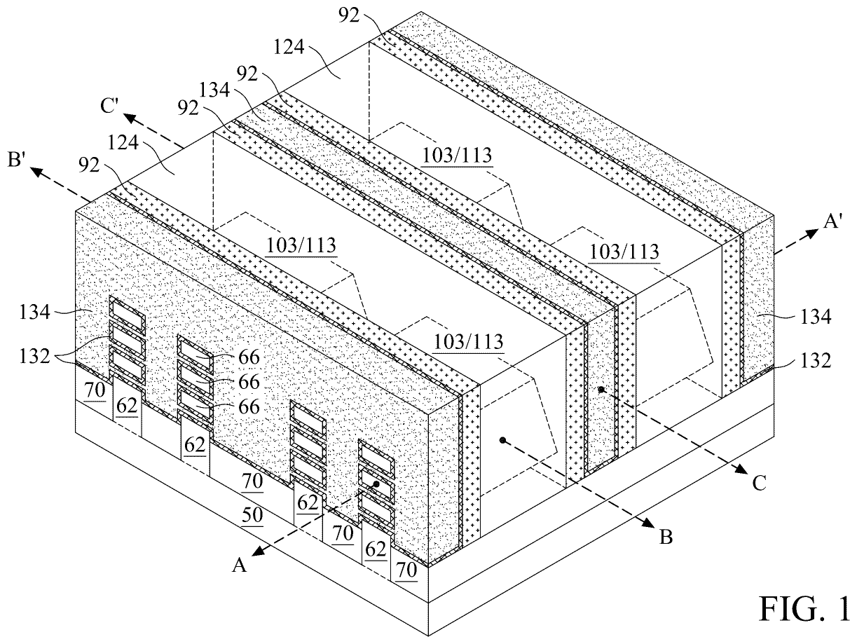

FIG. 1 illustrates an example of nanostructure-FETs (e.g., nanowire FETs, nanosheet FETs, gate-all-around (GAA) FETs, nano-FETs, or the like) in a three-dimensional view, in accordance with some embodiments. Some features of the nanostructure-FETs may be omitted from FIG. 1 for clarity. The nanostructure-FETs include nanostructures 66 (e.g., nanosheets, nanowires, or the like) over fins 62 on a substrate 50 (e.g., a semiconductor substrate), with the nanostructures 66 being semiconductor features that act as channel regions for the nanostructure-FETs. Isolation regions 70, such as shallow trench isolation (STI) regions, are disposed between adjacent fins 62, which may protrude above and from between neighboring isolation regions 70. The nanostructures 66 are disposed over and between adjacent isolation regions 70. Although the isolation regions 70 are described/illustrated as being separate from the substrate 50, as used herein, the term “substrate” may refer to the semiconductor substrate alone or a combination of the semiconductor substrate and the isolation regions. Additionally, although a bottom portion of the fins 62 are illustrated as being single, continuous materials with the substrate 50, the bottom portion of the fins 62 and/or the substrate 50 may comprise a single material or a plurality of materials. In this context, the fins 62 refer to the portion extending between the neighboring isolation regions 70.

Gate dielectrics 132 are over top surfaces of the fins 62 and along top surfaces, sidewalls, and bottom surfaces of the nanostructures 66. Gate electrodes 134 are over the gate dielectrics 132. Source/drain regions 113 are disposed on the fins 62 at opposing sides of the gate dielectrics 132 and the gate electrodes 134. Source/drain region(s) 113 may refer to a source or a drain, individually or collectively dependent upon the context. An inter-layer dielectric (ILD) 124 is formed over the source/drain regions 113. Contacts (subsequently described) to the source/drain regions 113 will be formed through the ILD 124. The source/drain regions 113 may be shared between various nanostructures 66. For example, adjacent source/drain regions 113 may be electrically connected, such as through coalescing or merging the source/drain regions 113 by epitaxial growth, or through coupling the source/drain regions 113 with a same contact.

FIG. 1 further illustrates reference cross-sections that are used in later figures. Cross-section A-A′ is along a longitudinal axis of a fin 62 of a nanostructure-FET and in a direction of, for example, a current flow between the source/drain regions 113 of the nanostructure-FET. Cross-section B-B′ is perpendicular to cross-section A-A′ and extends through source/drain regions 113 of the nanostructure-FETs. Cross-section C-C′ is parallel to cross-section B-B′ and along a longitudinal axis of a gate electrode 134. Subsequent figures refer to these reference cross-sections for clarity.

Some embodiments discussed herein are discussed in the context of nanostructure-FETs formed using a gate-last process. In other embodiments, a gate-first process may be used. Also, some embodiments contemplate aspects used in planar devices, such as planar FETs, or in fin field-effect transistors (FinFETs), in lieu of or in combination with the nanostructure-FETs. For example, FinFETs may include semiconductor fins on a substrate, with the semiconductor fins being semiconductor features which act as channel regions for the FinFETs. Similarly, planar FETs may include a substrate, with planar portions of the substrate being semiconductor features which act as channel regions for the planar FETs.

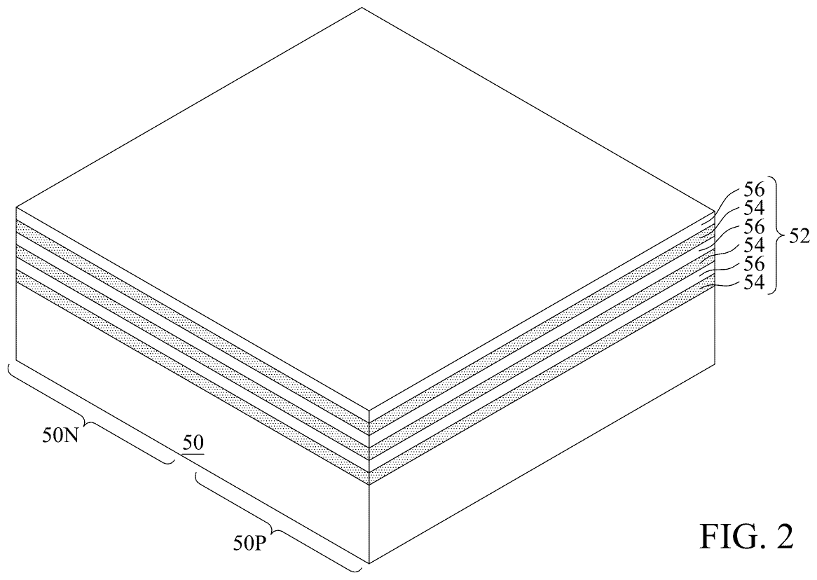

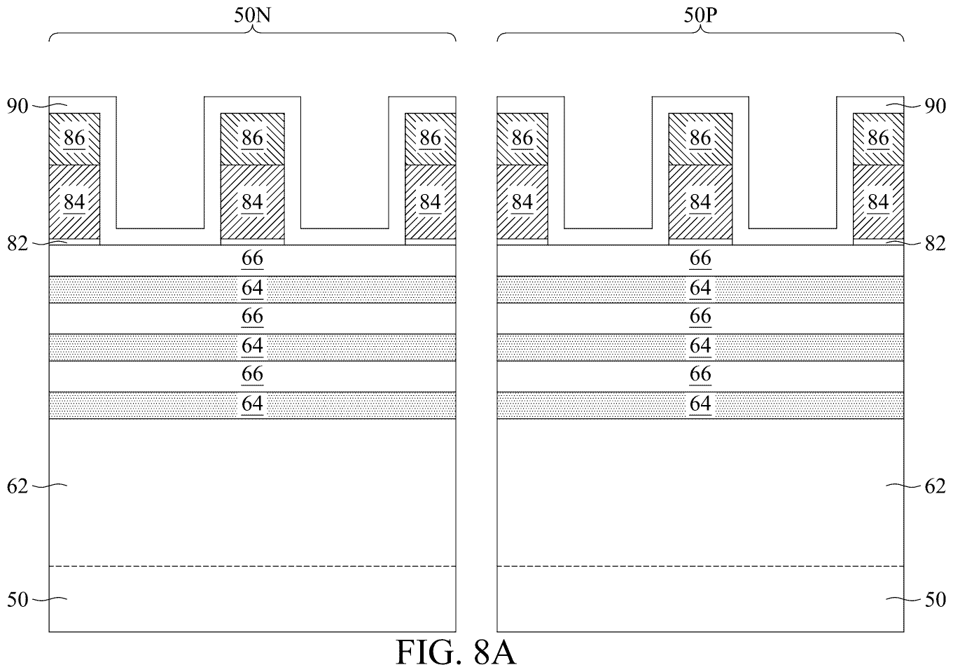

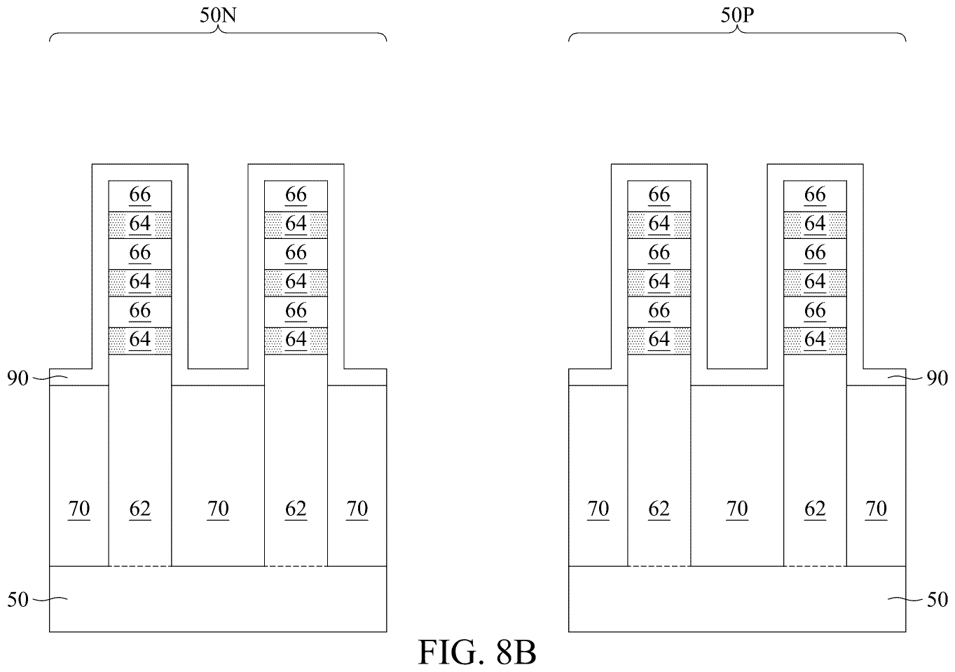

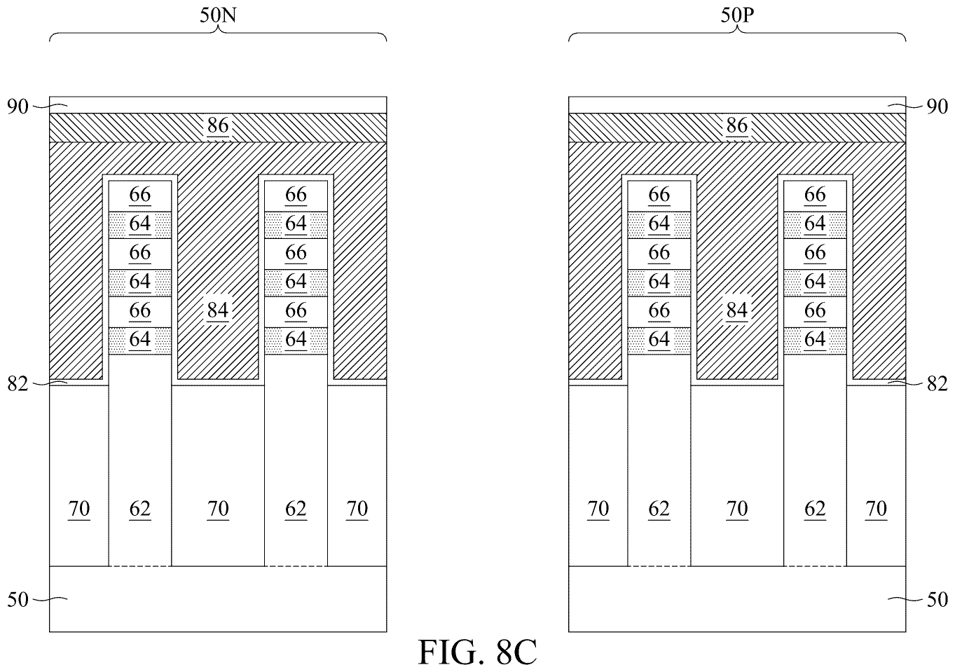

FIGS. 2-26C are views of intermediate stages in the manufacturing of nanostructure-FETs, in accordance with some embodiments. FIGS. 2, 3, 4, 5, 6, and 7 are three-dimensional views showing a similar three-dimensional view as FIG. 1. FIGS. 8A, 9A, 10, 11A, 12A, 13A, 14A, 15A, 16A, 17, 18, 19A, 19B, 20A, 21A, 22A, 23A, 24A, 25A, and 26A illustrate cross-sectional views along a similar cross-section as reference cross-section A-A′ in FIG. 1. FIGS. 8B, 9B, 10B, 11B, 12B, 13B, 14B, 15B, 16B, 18, 19A-19B, 20B, 21B, 22B, 23B, 24B, 25B, and 26B illustrate cross-sectional views along a similar cross-section as reference cross-section B-B′ in FIG. 1. FIGS. 8C, 9C, 10C, 11C, 12C, 13C, 14C, 15C, 16C, 20C, 21C, 22C, 23C, 24C, 25C, and 26C illustrate cross-sectional views along a similar cross-section as reference cross-section C-C′ in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nanostructure-FETs, and the p-type region 50P can be for forming p-type devices, such as PMOS transistors, e.g., p-type nanostructure-FETs. The n-type region 50N may (or may not) be physically separated (not separately illustrated) from the p-type region 50P, and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 52 is formed over the substrate 50. The multi-layer stack 52 includes alternating first semiconductor layers 54 and second semiconductor layers 56. The first semiconductor layers 54 are formed of a first semiconductor material, and the second semiconductor layers 56 are formed of a second semiconductor material. The semiconductor materials may each be selected from the candidate semiconductor materials of the substrate 50.

In the illustrated embodiment, and as subsequently described in greater detail, the first semiconductor layers 54 will be removed and the second semiconductor layers 56 will patterned to form channel regions for the nanostructure-FETs in both the n-type region 50N and the p-type region 50P. In such embodiments, the channel regions in both the n-type region 50N and the p-type region 50P may have a same material composition (e.g., silicon or another semiconductor material) and be formed simultaneously. The first semiconductor layers 54 are dummy layers that will be removed in subsequent processing to expose top surfaces and bottom surfaces of the second semiconductor layers 56. The first semiconductor material of the first semiconductor layers 54 is a material that has a high etching selectivity from the etching of the second semiconductor layers 56, such as silicon germanium. The second semiconductor material of the second semiconductor layers 56 is a material suitable for both n-type and p-type devices, such as silicon.

In another embodiment (not separately illustrated), the first semiconductor layers 54 will be patterned to form channel regions for nanostructure-FETs in one region (e.g., the p-type region 50P), and the second semiconductor layers 56 will be patterned to form channel regions for nanostructure-FETs in another region (e.g., the n-type region 50N). The first semiconductor material of the first semiconductor layers 54 may be a material suitable for p-type devices, such as silicon germanium (e.g., SiₓGe₁₋ₓ, where x can be in the range of 0 to 1), pure germanium, a III-V compound semiconductor, a II-VI compound semiconductor, or the like. The second semiconductor material of the second semiconductor layers 56 may be a material suitable for n-type devices, such as silicon, silicon carbide, a III-V compound semiconductor, a II-VI compound semiconductor, or the like. The first semiconductor material and the second semiconductor material may have a high etching selectivity from the etching of one another, so that the first semiconductor layers 54 may be removed without significantly removing the second semiconductor layers 56 in the n-type region 50N, and the second semiconductor layers 56 may be removed without significantly removing the first semiconductor layers 54 in the p-type region 50P.

The multi-layer stack 52 is illustrated as including three of the first semiconductor layers 54 and three of the second semiconductor layers 56. It should be appreciated that the multi-layer stack 52 may include any number of the first semiconductor layers 54 and the second semiconductor layers 56. Each of the layers of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like. In some embodiments, some layers of the multi-layer stack 52 are formed to be thinner than other layers of the multi-layer stack 52.

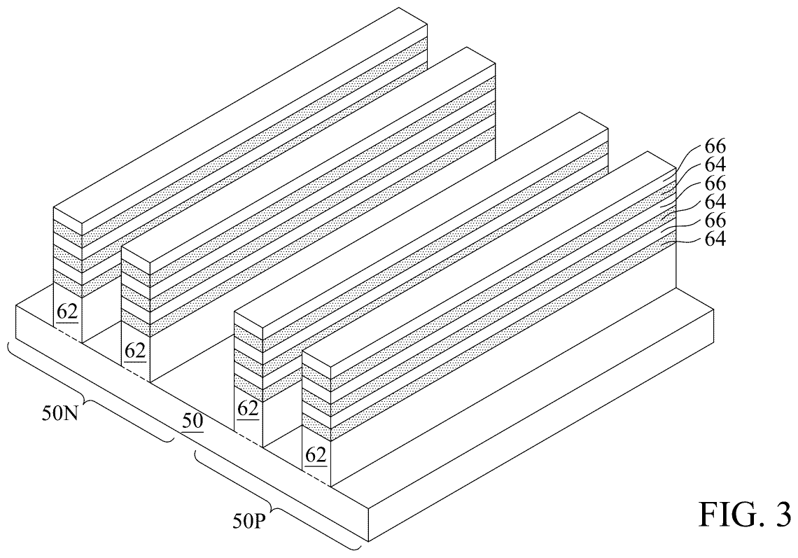

In FIG. 3, fins 62 are formed in the substrate 50, and nanostructures 64 and nanostructures 66 (collectively referred to as “nanostructures 64/66”) are formed in the multi-layer stack 52. In some embodiments, the nanostructures 64/66 and the fins 62 may be formed in the multi-layer stack 52 and the substrate 50, respectively, by etching trenches in the multi-layer stack 52 and the substrate 50. The etching may be any acceptable etch process, such as a reactive ion etch (RIE), neutral beam etch (NBE), the like, or a combination thereof. The etching may be anisotropic. Forming the nanostructures 64/66 by etching the multi-layer stack 52 may further define first nanostructures 64 from the first semiconductor layers 54 and define second nanostructures 66 from the second semiconductor layers 56.

The fins 62 and the nanostructures 64/66 may be patterned by any suitable method. For example, the fins 62 and the nanostructures 64/66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 62 and the nanostructures 64/66.

The fins 62 are illustrated as having substantially equal widths in both the n-type region 50N and the p-type region 50P. In some embodiments, the widths of the fins 62 in the n-type region 50N may be greater or less than the width of the fins 62 in the p-type region 50P. Further, while each of the fins 62 and the nanostructures 64/66 are illustrated as having a constant width throughout, in other embodiments, the fins 62 and/or the nanostructures 64/66 may have tapered sidewalls such that a width of each of the fins 62 and/or the nanostructures 64/66 continuously increases in a direction towards the substrate 50. In such embodiments, each of the nanostructures 64/66 may have a different width and may be trapezoidal in shape.

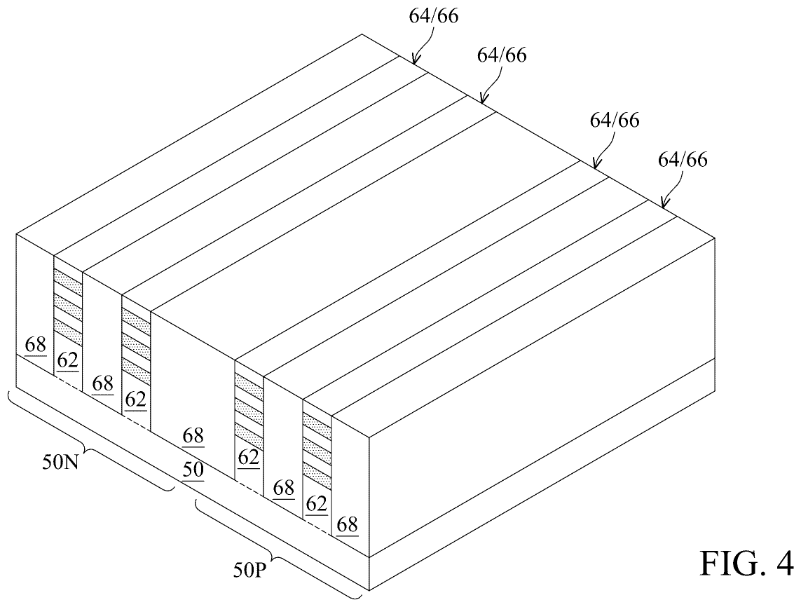

In FIG. 4, an insulation material 68 is formed over the substrate 50 and between adjacent fins 62 and adjacent nanostructures 64/66. The insulation material 68 may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In some embodiments, the insulation material 68 includes silicon oxide formed by an FCVD process. An annealing process may be performed once the insulation material 68 is formed. Although the insulation material 68 is illustrated as a single layer, some embodiments may utilize multiple layers. For example, in some embodiments a liner (not separately illustrated) may first be formed along a surface of the substrate 50, the fins 62, and the nanostructures 64/66. Thereafter, a fill material, such as one of the previously described insulation materials may be formed over the liner.

The insulation material 68 may be deposited over the fins 62 and nanostructures 64/66 such that excess insulation material 68 covers the nanostructures 64/66. A removal process is then applied to the insulation material 68 to remove excess insulation material 68 over the nanostructures 64/66. In some embodiments, a planarization process such as a chemical mechanical polish (CMP), an etch-back process, combinations thereof, or the like may be utilized. The planarization process exposes the nanostructures 64/66 such that top surfaces of the nanostructures 64/66 and the insulation material 68 are level after the planarization process is complete.

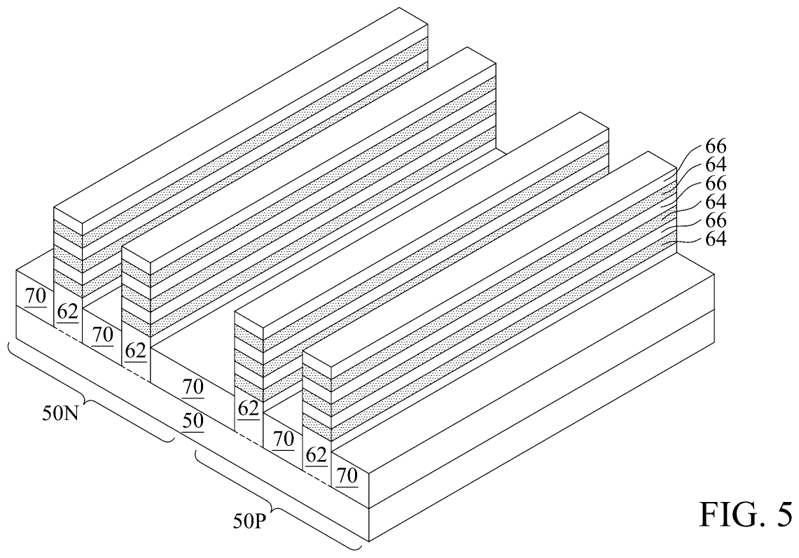

In FIG. 5, the insulation material 68 is recessed to form STI regions 70. The STI regions 70 are adjacent the fins 62. The insulation material 68 is recessed such that upper portions of fins 62 and/or the nanostructures 64/66 protrude from between neighboring STI regions 70. The upper portions of the fins 62 and/or the nanostructures 64/66 are above the STI regions 70. Further, the top surfaces of the STI regions 70 may have a flat surface as illustrated, a convex surface, a concave surface (such as dishing), or a combination thereof. The top surfaces of the STI regions 70 may be formed flat, convex, and/or concave by an appropriate etch. The STI regions 70 may be recessed using an acceptable etching process, such as one that is selective to the material of the insulation material 68 (e.g., etches the material of the insulation material 68 at a faster rate than the materials of the fins 62 and the nanostructures 64/66). For example, an oxide removal using, for example, dilute hydrofluoric (dHF) acid may be used.

The previously described process is just one example of how the fins 62 and the nanostructures 64/66 may be formed. In some embodiments, the fins 62 and/or the nanostructures 64/66 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 62 and/or the nanostructures 64/66. The epitaxial structures may comprise the previously described alternating semiconductor materials, such as the first semiconductor materials and the second semiconductor materials. In some embodiments in which epitaxial structures are epitaxially grown, the epitaxially grown materials may be in situ doped during growth, which may obviate prior and/or subsequent implantations, although in situ and implantation doping may be used together.

Further, appropriate wells (not separately illustrated) may be formed in the fins 62, the nanostructures 64/66, and/or the STI regions 70. In embodiments with different well types, different implant steps for the n-type region 50N and the p-type region 50P may be achieved using a photoresist or other mask (not separately illustrated). For example, a photoresist may be formed over the fins 62, the nanostructures 64/66, and the STI regions 70 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other mask (not separately illustrated) is formed over the fins 62, the nanostructures 64/66, and the STI regions 70 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

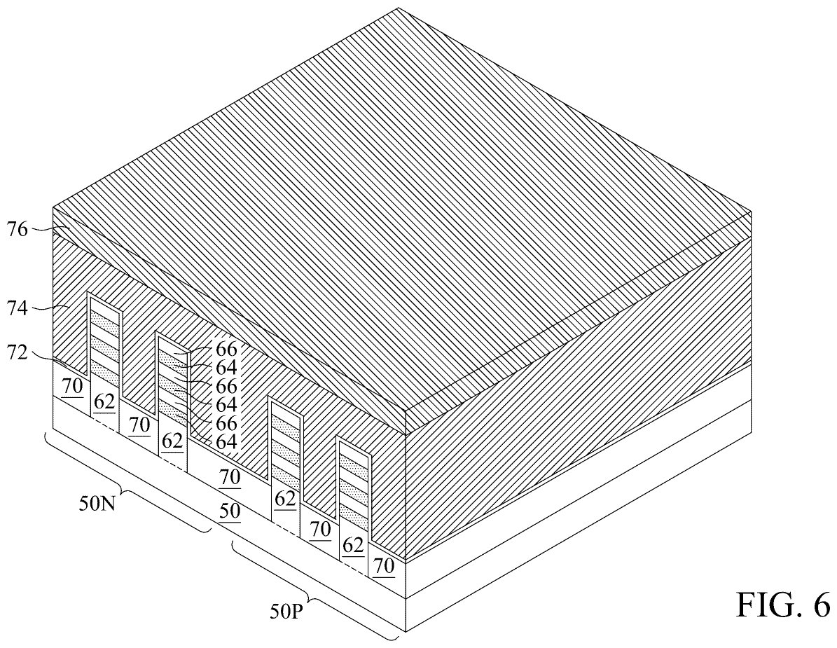

In FIG. 6, a dummy dielectric layer 72 is formed on the fins 62 and/or the nanostructures 64/66. The dummy dielectric layer 72 may be formed of silicon oxide, silicon nitride, a combination thereof, or the like, which may be deposited or thermally grown according to acceptable techniques. A dummy gate layer 74 is formed over the dummy dielectric layer 72, and a mask layer 76 is formed over the dummy gate layer 74. The dummy gate layer 74 may be deposited over the dummy dielectric layer 72 and then planarized, such as by a CMP. The dummy gate layer 74 may be formed of a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The material of the dummy gate layer 74 may be deposited by CVD, physical vapor deposition (PVD), sputter deposition, or other techniques for depositing the selected material. The dummy gate layer 74 may be formed of other materials that have a high etching selectivity from the etching of insulation materials, e.g., the STI regions 70 and/or the dummy dielectric layer 72. The mask layer 76 may be deposited over the dummy gate layer 74. The mask layer 76 may be formed of a dielectric material such as silicon nitride, silicon oxynitride, or the like. In this example, a single dummy gate layer 74 and a single mask layer 76 are formed across the n-type region 50N and the p-type region 50P. In the illustrated embodiment, the dummy dielectric layer 72 covers the STI regions 70, such that the dummy dielectric layer 72 extends between the dummy gate layer 74 and the STI regions 70. In another embodiment, the dummy dielectric layer 72 covers only the fins 62 and/or the nanostructures 64/66.

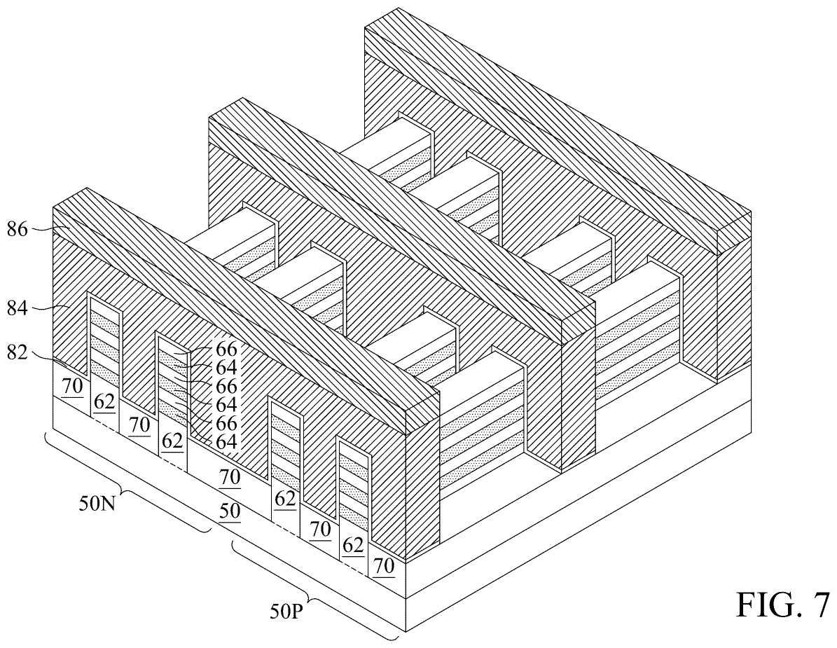

In FIG. 7, the mask layer 76 is patterned using acceptable photolithography and etching techniques to form masks 86. The pattern of the masks 86 then may be transferred to the dummy gate layer 74 and to the dummy dielectric layer 72 to form dummy gates 84 and dummy dielectrics 82, respectively. The dummy gates 84 cover respective channel regions of the nanostructures 64/66. The pattern of the masks 86 may be used to physically separate each of the dummy gates 84 from adjacent dummy gates 84. The dummy gates 84 may also have a lengthwise direction substantially perpendicular to the lengthwise direction of respective fins 62. The masks 86 can optionally be removed after patterning, such as by any acceptable etching technique.

In FIGS. 8A-8C, a spacer layer 90 is conformally formed over the nanostructures 64/66 and the STI regions 70, on exposed sidewalls of the masks 86 (if present), the dummy gates 84, the dummy dielectrics 82, the nanostructures 64/66, and the fins 62. The spacer layer 90 may be formed of one or more dielectric material(s). FIGS. 8A-8C show a spacer layer 90 formed of a single layer of dielectric material, but in other embodiments the spacer layer 90 may be formed of two or more layers of dielectric materials. Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. The spacer layer 90 will be subsequently etched to form spacers.

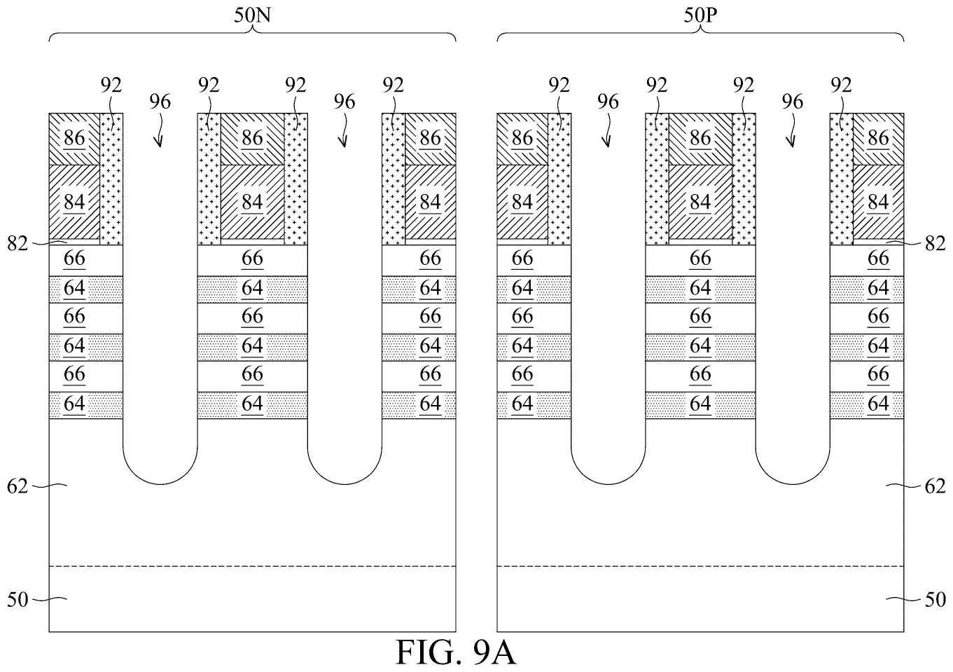

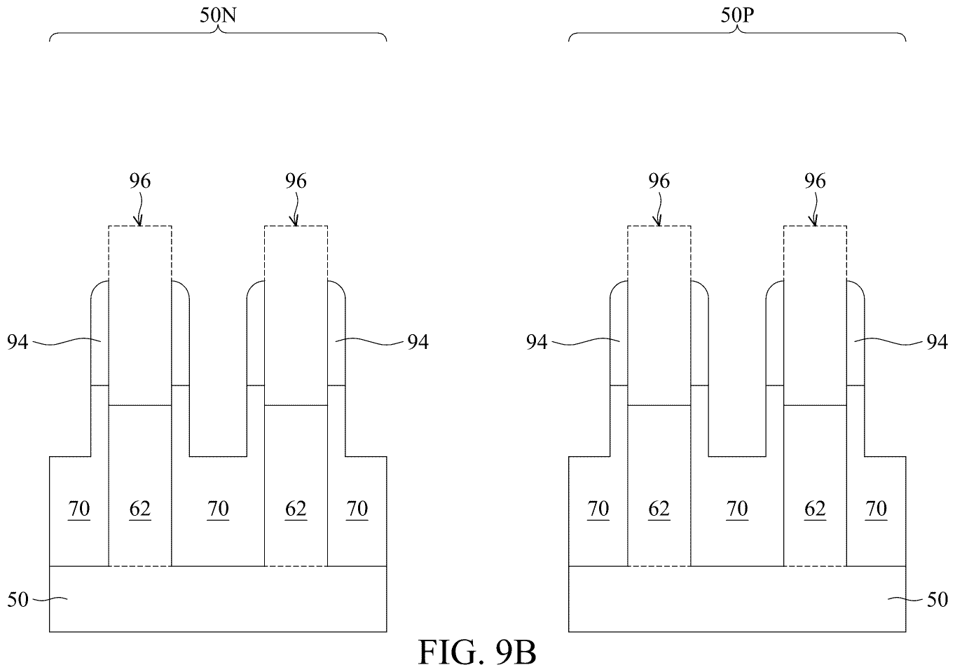

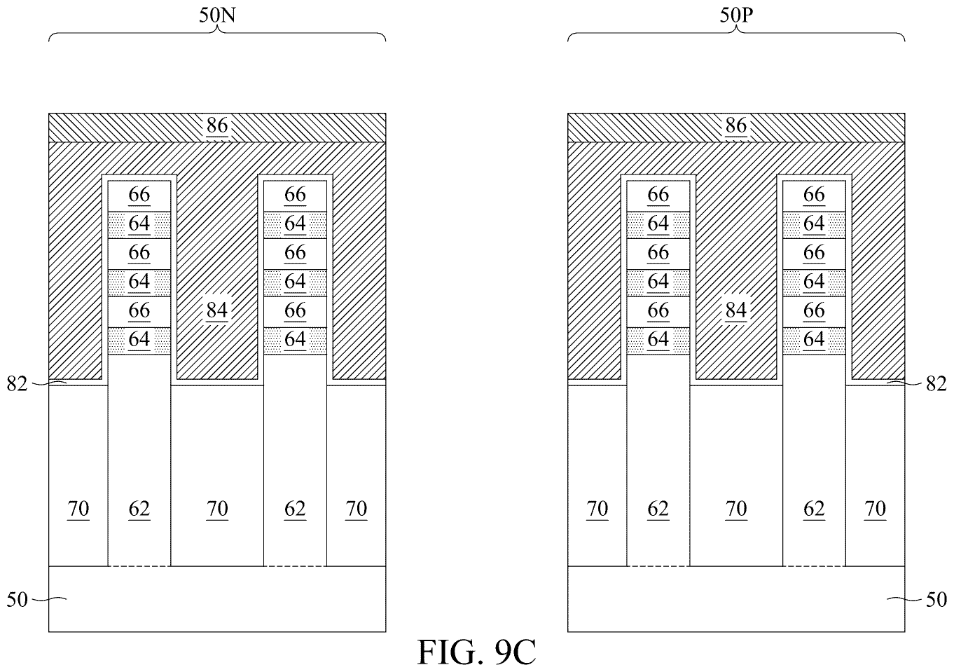

In FIGS. 9A-9C, the spacer layer 90 is patterned to form gate spacers 92 and fin spacers 94. Any acceptable etch process, such as a dry etch, a wet etch, the like, or a combination thereof, may be performed to pattern the spacer layer 90. The etching may be anisotropic. The spacer layer 90, when etched, has portions left on the sidewalls of the dummy gates 84 (thus forming the gate spacers 92) and has portions left on the sidewalls of the fins 62 and/or the nanostructures 64/66 (thus forming the fin spacers 94). After etching, the fin spacers 94 and/or the gate spacers 92 can have straight sidewalls or can have curved sidewalls. Additionally, the STI regions 70 may also be etched when patterning the spacer layer 90. The etching may recess portions of the STI regions 70 between the fins 62.

Further, implants for lightly doped source/drain (LDD) regions (not separately illustrated) may be performed. In embodiments with different device types, similar to the implants for the previously described wells, a mask, such as a photoresist, may be formed over the n-type region 50N, while exposing the p-type region 50P, and appropriate type (e.g., p-type) impurities may be implanted into the fins 62 and the nanostructures 64/66 exposed in the p-type region 50P. The mask may then be removed. Subsequently, a mask, such as a photoresist, may be formed over the p-type region 50P while exposing the n-type region 50N, and appropriate type impurities (e.g., n-type) may be implanted into the fins 62 and the nanostructures 64/66 exposed in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 10¹⁵ atoms/cm³ to about 10¹⁹ atoms/cm³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

Still referring to FIGS. 9A-9C, source/drain recesses 96 are patterned in the fins 62, the nanostructures 64/66, and the substrate 50, in accordance with some embodiments. Epitaxial source/drain regions are subsequently formed in the source/drain recesses 96. The source/drain recesses 96 may extend through the nanostructures 64/66 and into the substrate 50. In some embodiments, the fins 62 may be etched such that bottom surfaces of the source/drain recesses 96 are disposed below the top surfaces of the STI regions 70. The source/drain recesses 96 may be formed by etching the fins 62, the nanostructures 64/66, and the substrate 50 using anisotropic etching processes, such as RIE, NBE, or the like. In some embodiments, the gate spacers 92 and the dummy gates 84 mask portions of the fins 62, the nanostructures 64/66, and the substrate 50 during the etching processes used to form the source/drain recesses 96. A single etch process or multiple etch processes may be used to etch each layer of the nanostructures 64/66 and/or the fins 62. Timed etch processes may be used to stop the etching of the source/drain recesses 96 after the source/drain recesses 96 reach a desired depth.

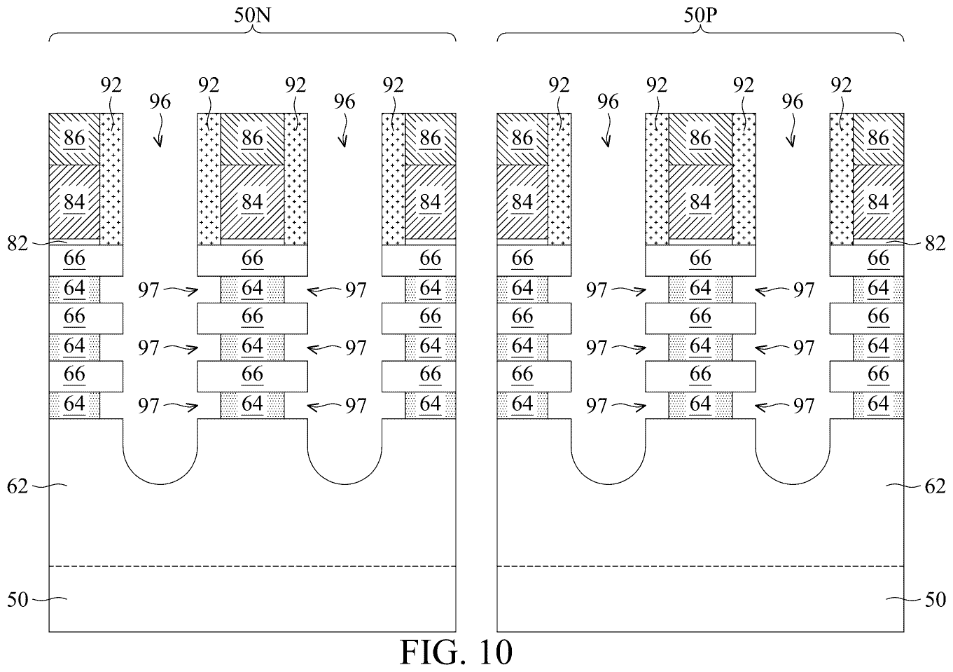

In FIG. 10, the source/drain recesses 96 are laterally expanded to form sidewall recesses 97 in the first nanostructures 64, in accordance with some embodiments. Specifically, portions of the sidewalls of the first nanostructures 64 exposed by the source/drain recesses 96 may be recessed to form sidewall recesses 97. Accordingly, a sidewall recess 97 may have a height that is about the same as a height (e.g., a thickness) of its corresponding first nanostructure 64. Although sidewalls of the first nanostructures 64 within the sidewall recesses 97 are illustrated as being flat, the sidewalls may be concave or convex. The sidewalls may be recessed by any acceptable etch process, such as one that is selective to the material of the first nanostructures 64 (e.g., selectively etches the material of the first nanostructures 64 at a faster rate than the material of the second nanostructures 66). The etching may be isotropic. For example, when the second nanostructures 66 are formed of silicon and the first nanostructures 64 are formed of silicon germanium, the etch process may be a wet etch using tetramethylammonium hydroxide (TMAH), ammonium hydroxide (NH₄OH), or the like. In another embodiment, the etch process may be a dry etch using a fluorine-based gas such as hydrogen fluoride (HF) gas. In some cases, the etch process may slightly recess (e.g., remove portions of) the second nanostructures 66 exposed by the sidewall recesses 97 as the sidewall recesses 97 are formed (not illustrated). In such cases, a sidewall recess 97 may have a height that is larger than the height (e.g., the thickness) of its corresponding first nanostructure 64. In some embodiments, the same etch process may be continually performed to both form the source/drain recesses 96 and recess the sidewalls of the first nanostructures 64 to form the sidewall recesses 97. In some cases, the sidewall recesses 97 may be considered part of the source/drain recesses 96.

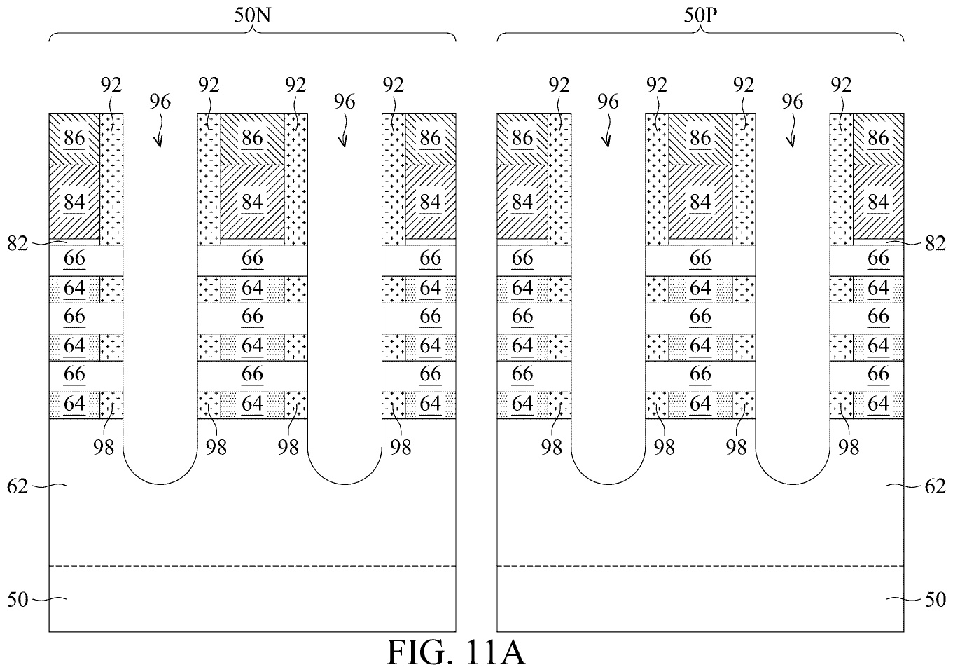

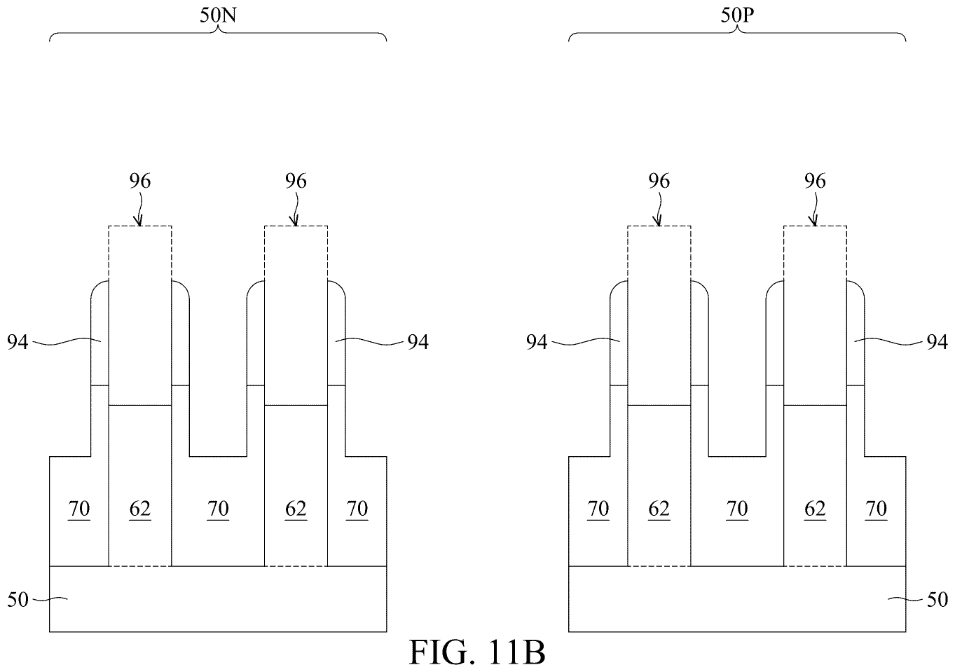

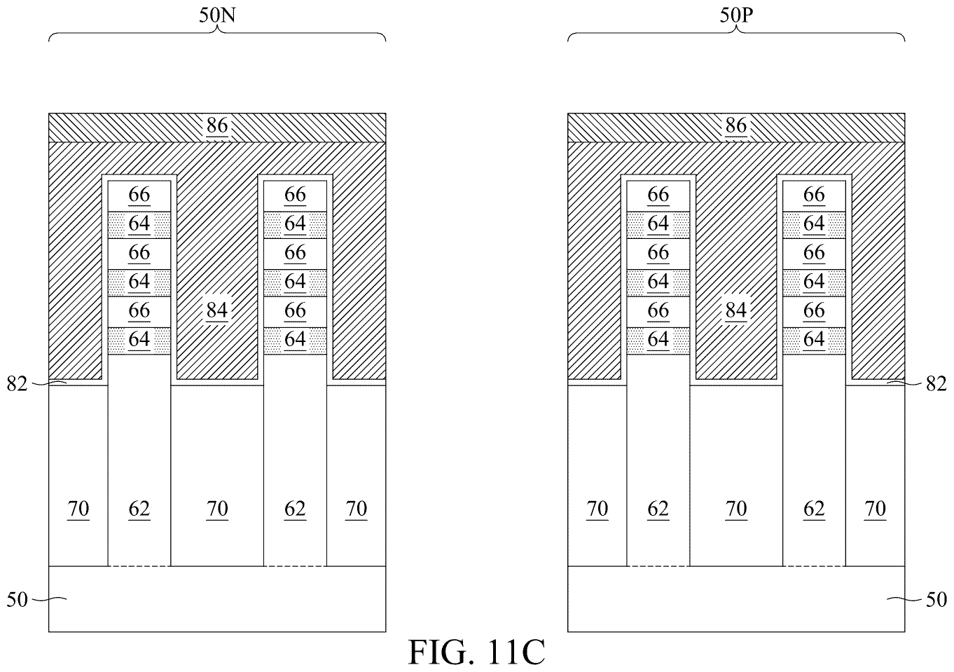

In FIGS. 11A-11C, inner spacers 98 are in the sidewall recesses 97, in accordance with some embodiments. In other words, the inner spacers 98 are formed on the sidewalls of the remaining portions of the first nanostructures 64. As will be subsequently described in greater detail, source/drain regions will be subsequently formed in the source/drain recesses 96, and the first nanostructures 64 will be subsequently replaced with corresponding gate structures. The inner spacers 98 act as isolation features between the subsequently formed source/drain regions and the subsequently formed gate structures. Further, the inner spacers 98 may be used to prevent damage to the subsequently formed source/drain regions by subsequent etch processes, such as etch processes used to subsequently remove the first nanostructures 64.

In some embodiments, the inner spacers 98 are formed by conformally forming an insulating material in the source/drain recesses 96 and in the sidewall recesses 97, and subsequently etching the insulating material. The insulating material may be silicon nitride or silicon oxynitride, although any suitable material, such as low-dielectric constant (low-k) materials having a k-value less than about 3.5, may be utilized. The insulating material may be formed by a deposition process, such as ALD, CVD, or the like. The etching of the insulating material may be anisotropic. For example, the etch process may be a dry etch such as a RIE, a NBE, or the like. After performing the etching of the insulating material, the remaining portions of the insulating material within the sidewall recesses 97 form the inner spacers 98.

Although outer sidewalls of inner spacers 98 are illustrated as being flush (e.g. approximately coplanar) with sidewalls of the second nanostructures 66, the outer sidewalls of the inner spacers 98 may extend beyond or be recessed from sidewalls of the second nanostructures 66. In other words, the inner spacers 98 may partially fill, completely fill, or overfill the sidewall recesses 97. Moreover, although the sidewalls of the inner spacers 98 are illustrated as being flat, the sidewalls of the inner spacers 98 may be concave or convex. In some embodiments, an inner spacer 98 may have a thickness that is about the same as or greater than a thickness of an adjacent first nanostructure 64.

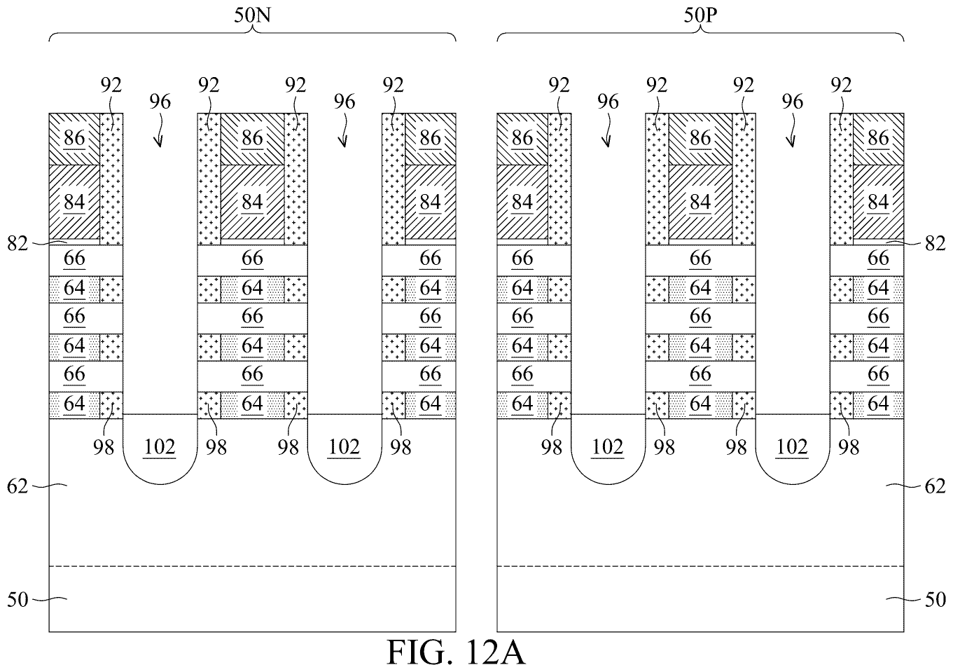

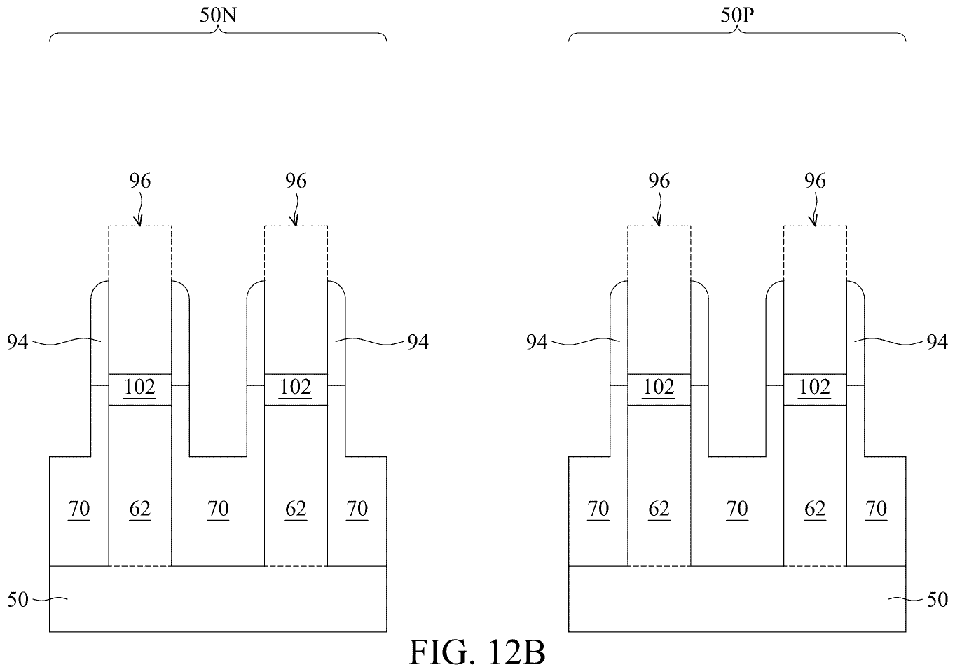

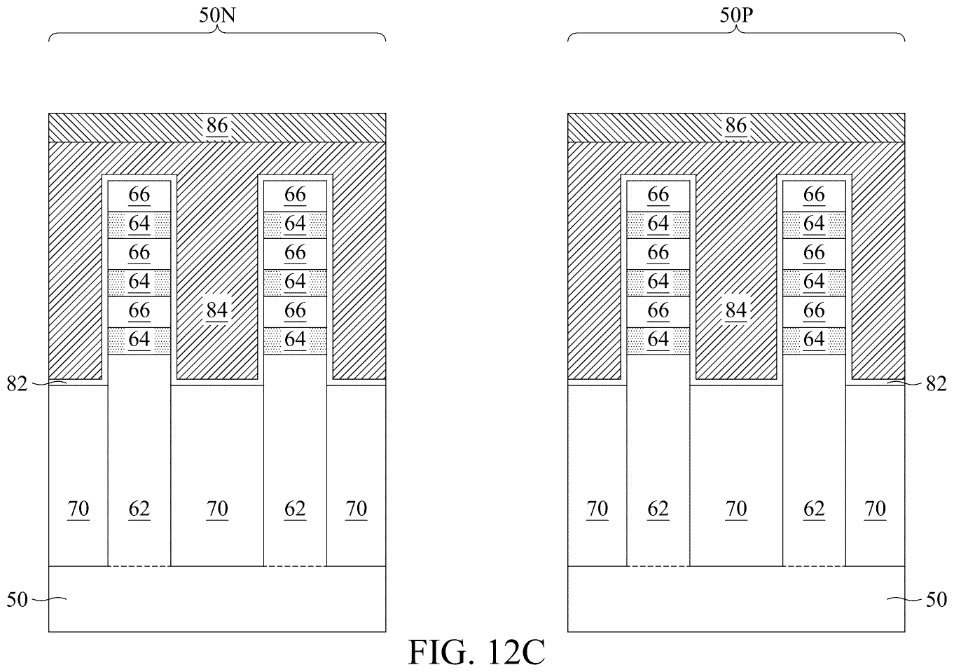

In FIGS. 12A-12C, semiconductor layers 102 are formed in the source/drain recesses 96, in accordance with some embodiments. The semiconductor layers 102 may be formed of a semiconductor material selected from the candidate semiconductor materials of the substrate 50, which may be grown by an epitaxial growth process such as vapor phase epitaxy (VPE), molecular beam epitaxy (MBE), or the like. The semiconductor layers 102 may be undoped semiconductor layers. In some embodiments, the semiconductor layers 102 are formed of undoped silicon or undoped silicon germanium. In this embodiment, the top surfaces of the semiconductor layers 102 are flat top surfaces. Although the top surfaces of the semiconductor layers 102 are illustrated as being flat (e.g., planar), the top surfaces of the semiconductor layers 102 may be concave or convex.

In some embodiments, the semiconductor layers 102 may be epitaxially grown by flowing a semiconductor-containing precursor and an etchant-containing precursor in the source/drain recesses 96. The semiconductor-containing precursor may be a silicon-containing precursor such as a silane, such as monosilane (SiH₄), dichlorosilane (H₂SiCl₂), disilane (Si₂H₆), or the like; a germanium-containing precursor such as germane (GeH₄) or the like; combinations thereof; or the like. The etchant-containing precursor may be a chlorine-containing precursor such as hydrogen chloride (HCl) gas, chlorine (Cl₂) gas, or the like. The etchant-containing precursor is flowed at a fast flow rate, which may cause the semiconductor layers 102 to be grown in more of a bottom-up manner than a lateral manner. In some embodiments, the semiconductor-containing precursor is flowed at a flow rate in the range of about 1000 sccm or less, and the etchant-containing precursor is flowed at a flow rate in the range of about 1000 sccm or less. As such, the semiconductor layers 102 may be grown from the fins 62 but not from the nanostructures 66. In some embodiments, the epitaxial growth is performed at a temperature in the range of about 500° C. to about 900° C., and at a pressure in the range of about 1 Torr to about 150 Torr. Other process parameters are possible. The semiconductor layers 102 may be formed with flat, convex, or concave top surfaces by controlling the flow rate of the etchant-containing precursor during deposition.

The semiconductor layers 102 may partially fill, completely fill, or overfill the portions of the source/drain recesses 96 that extend into the fins 62. Accordingly, top surfaces of the semiconductor layers 102 may be higher than, approximately level with, or below top surfaces of the fins 62. In some embodiments, the semiconductor layers 102 may be in physical contact with the sidewalls of some of the inner spacers 98. In other embodiments, the semiconductor layers 102 are not in physical contact with the inner spacers 98. In some embodiments, the semiconductor layers 102 are not in physical contact with the sidewalls of the nanostructures 66. Timed epitaxial growth processes may be used to stop the growth of the semiconductor layers 102 after the semiconductor layers 102 reach a desired height.

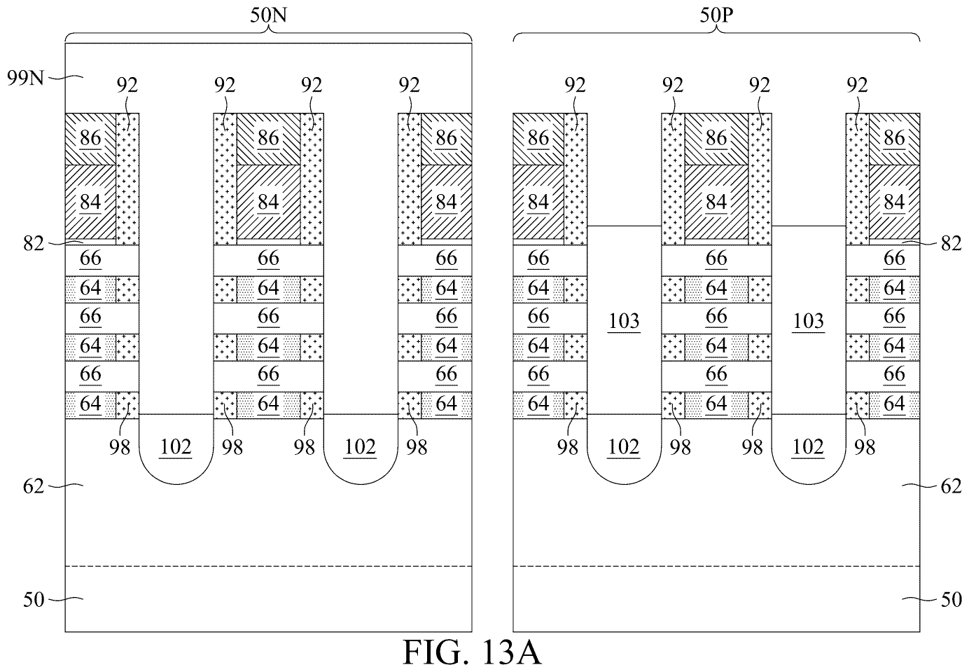

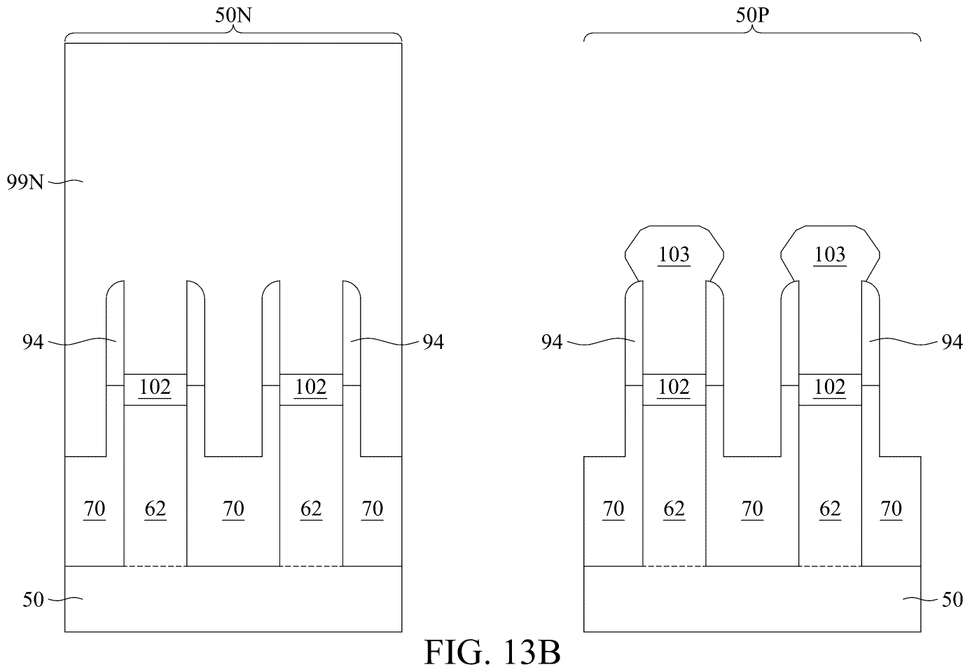

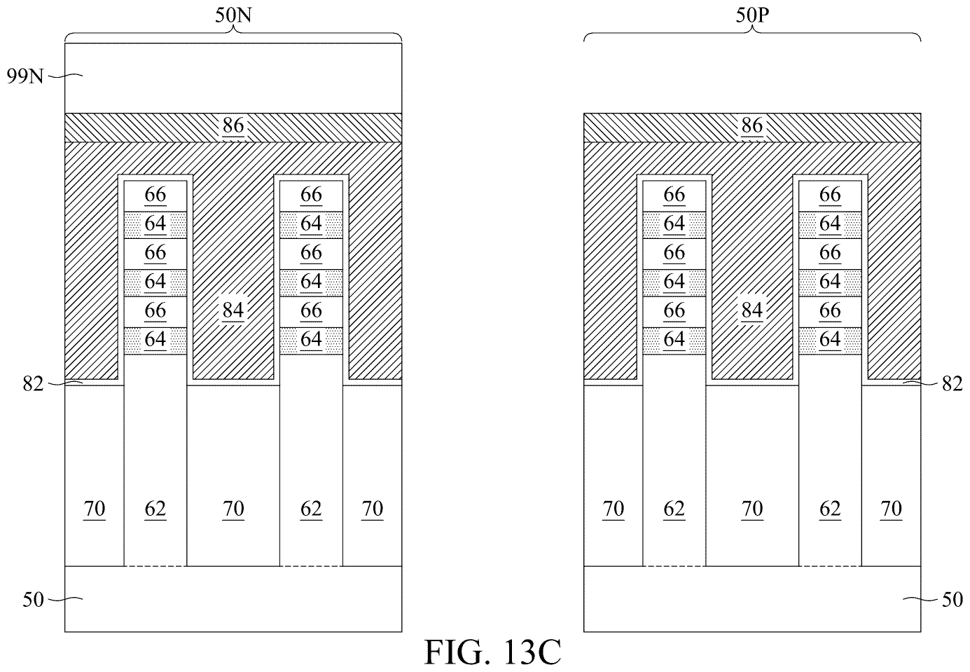

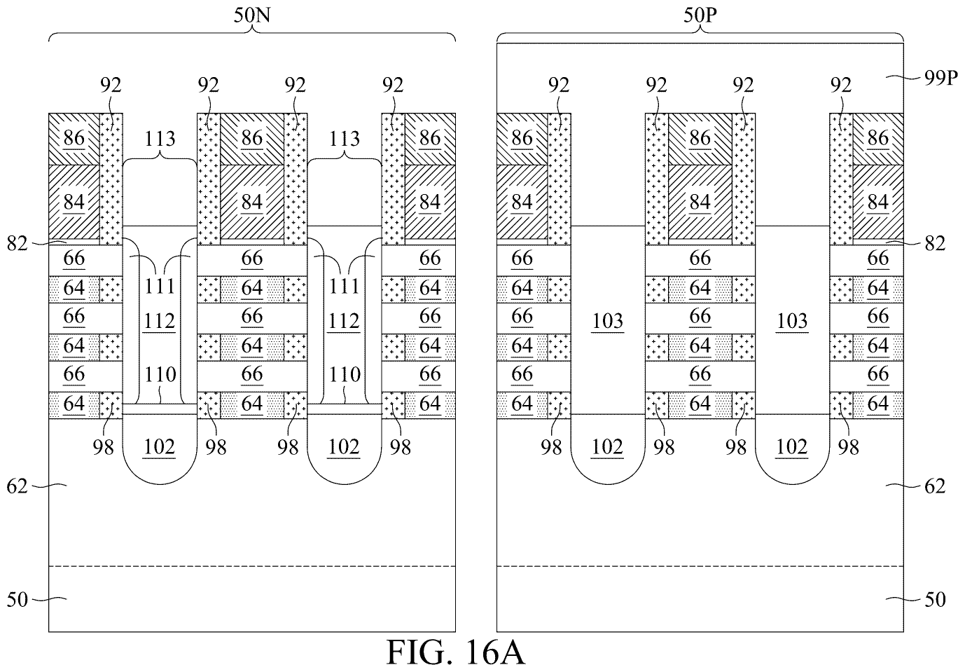

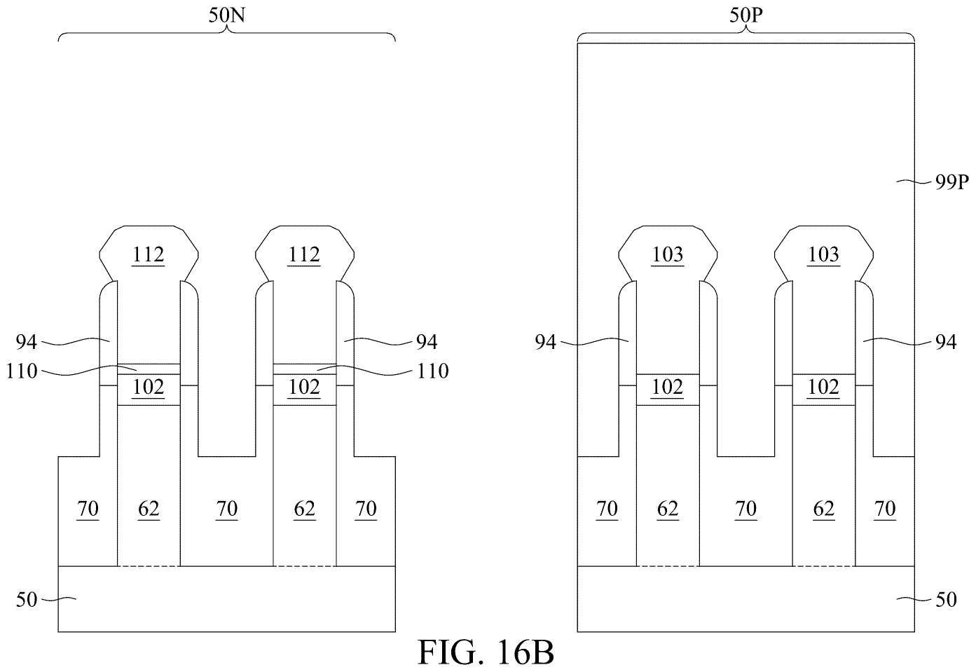

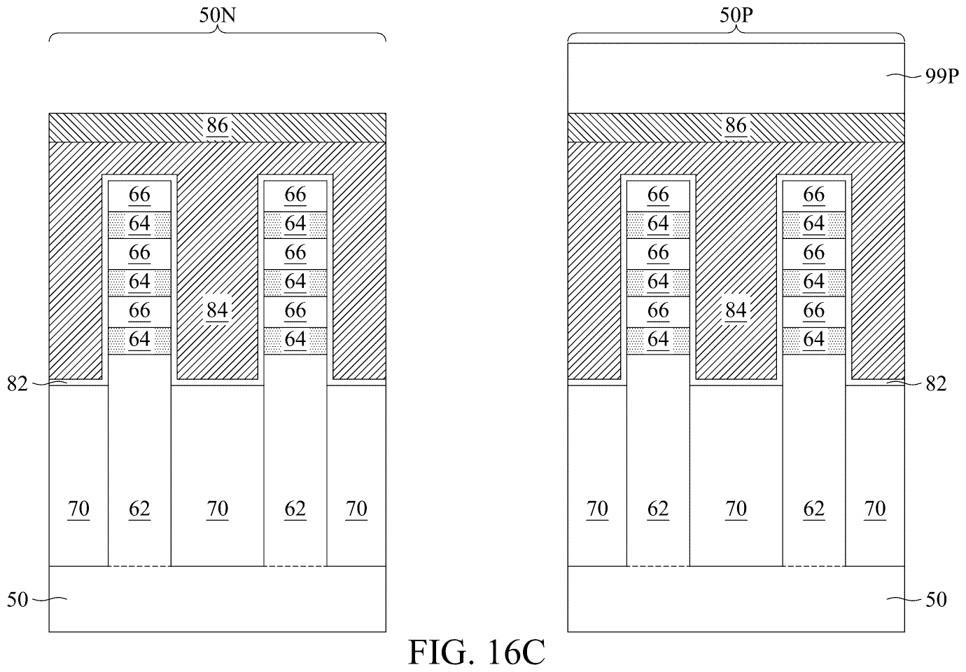

In FIGS. 13A-13C, epitaxial source/drain regions 103 are formed in the source/drain recesses 96 of the p-type region 50P, in accordance with some embodiments. The epitaxial source/drain regions 103 in the p-type region 50P may be referred to as “p-type source/drain regions.” The illustrated embodiment describes p-type source/drain regions 103 being formed in the p-type region 50P before n-type source/drain regions 113 are formed in the n-type region 50N (see FIGS. 16A-16B). For example, during formation of the p-type source/drain regions 103, the n-type region 50N may be covered by a mask 99N, which may be a hard mask, a photoresist mask, or the like. The mask 99N is removed after formation of the p-type source/drain regions 103 using a suitable process, such as an etching process, an ashing process, or the like. In other embodiments, the n-type source/drain regions 113 in the n-type region 50N may be formed before the p-type source/drain regions 103 are formed in the p-type region 50P. In the following discussion of FIGS. 13A-13C, the described features are within the p-type region 50P unless specifically indicated.

In some embodiments, the epitaxial source/drain regions 103 exert stress in the respective channel regions of the second nanostructures 66 within the p-type region 50P, thereby improving performance. The epitaxial source/drain regions 103 are formed in the source/drain recesses 96 such that each dummy gate 84 of the p-type region 50P is disposed between respective neighboring pairs of the epitaxial source/drain regions 103. In some embodiments, the gate spacers 92 are used to separate the epitaxial source/drain regions 103 from the dummy gates 84, and the inner spacers 98 are used to separate the epitaxial source/drain regions 103 from the nanostructures 64 by an appropriate lateral distance such that the epitaxial source/drain regions 103 do not short out with subsequently formed gates of the resulting p-type nanostructure-FETs.

The epitaxial source/drain regions 103 in the p-type region 50P may be formed by an epitaxy process (subsequently described). The epitaxial source/drain regions 103 may include any acceptable material appropriate for p-type nanostructure-FETs. For example, if the second nanostructures 66 are formed of silicon, the epitaxial source/drain regions 103 may comprise materials exerting a compressive strain on the first nanostructures 64, such as silicon-germanium, boron doped silicon-germanium, germanium, germanium tin, or the like. The epitaxial source/drain regions 103 may also have surfaces raised from respective surfaces of the nanostructures 64/66 and may have facets.

The epitaxial source/drain regions 103 are epitaxially grown in the source/drain recesses 96 in the p-type region 50P. The mask 99N substantially prevents growth in the n-type region 50N. The epitaxy processes used to form the epitaxial source/drain regions 103 are performed such that the epitaxial source/drain regions 103 are selectively grown from semiconductor features (e.g., the second nanostructures 66) and do not grow from dielectric features (e.g., the inner spacers 98). The epitaxial source/drain regions 103 may be grown by flowing a semiconductor-containing precursor, an etchant-containing precursor, and a dopant-containing precursor in the source/drain recesses 96. The semiconductor-containing precursor and the etchant-containing precursor may be selected from, respectively, the same semiconductor-containing precursors and etchant-containing precursors for growing the semiconductor layers 102, or may include different precursors. The dopant-containing precursor contains an appropriate dopant for p-type source/drain regions, such as a boron-containing precursor, such as diborane (B₂H₆), borane (BH₃), or the like. The etchant-containing precursor may be flowed at a slower flow rate when growing the epitaxial source/drain regions 103 than when growing the semiconductor layers 102, which may cause the epitaxial source/drain regions 103 to be grown in more of a lateral manner than a bottom-up manner. In some embodiments, the semiconductor-containing precursor is flowed at a flow rate in the range of about 1000 sccm or less, the etchant-containing precursor is flowed at a flow rate in the range of about 1000 sccm or less, and the dopant-containing precursor is flowed at a flow rate in the range of about 1000 sccm or less. The epitaxy process for the epitaxial source/drain regions 103 may have a faster lateral growth rate and a slower bottom-up growth rate than the epitaxy process for the semiconductor layers 102. As such, the epitaxial source/drain regions 103 may grow laterally from the second nanostructures 66. In some embodiments, the epitaxial growth is performed at a temperature in the range of about 400° C. to about 900° C. or at a pressure in the range of about 1 Torr to about 150 Torr. Other precursors or process parameters are possible.

The epitaxial source/drain regions 103, the nanostructures 64/66, and/or the fins 62 within the p-type region 50P may be implanted with dopants, similar to the process previously discussed for forming lightly-doped source/drain regions, followed by an anneal. The epitaxial source/drain regions 103 may have an impurity concentration of between about 10¹⁹ atoms/cm³ to about 10²¹ atoms/cm³. Other concentrations are possible. In some embodiments, the epitaxial source/drain regions 103 may be in situ doped during growth.

As a result of the epitaxy processes used to form the epitaxial source/drain regions 103, upper surfaces of the epitaxial source/drain regions 103 can have facets which expand laterally outward beyond sidewalls of the nanostructures 64/66. In some embodiments, these facets cause adjacent epitaxial source/drain regions 103 of a same nanostructure-FET to merge. In other embodiments, adjacent epitaxial source/drain regions 103 remain separated after the epitaxy process is completed, as illustrated by FIG. 13B. In the illustrated embodiments, the fin spacers 94 are formed on top surfaces of the STI regions 70, thereby blocking the epitaxial growth. In some other embodiments, the fin spacers 94 may cover portions of the sidewalls of the nanostructures 64/66 and/or the fins 62, further blocking the epitaxial growth. In another embodiment, the spacer etch used to form the gate spacers 92 is controlled to not form the fin spacers 94, so as to allow the epitaxial source/drain regions 103 to extend to the surface of the STI region 70. In some embodiments, the epitaxial source/drain regions 103 extend above the top surface of the nanostructures 66. As a result, the top surface of an epitaxial source/drain region 103 is disposed further from the substrate 50 than the top surface of the adjacent nanostructures 66.

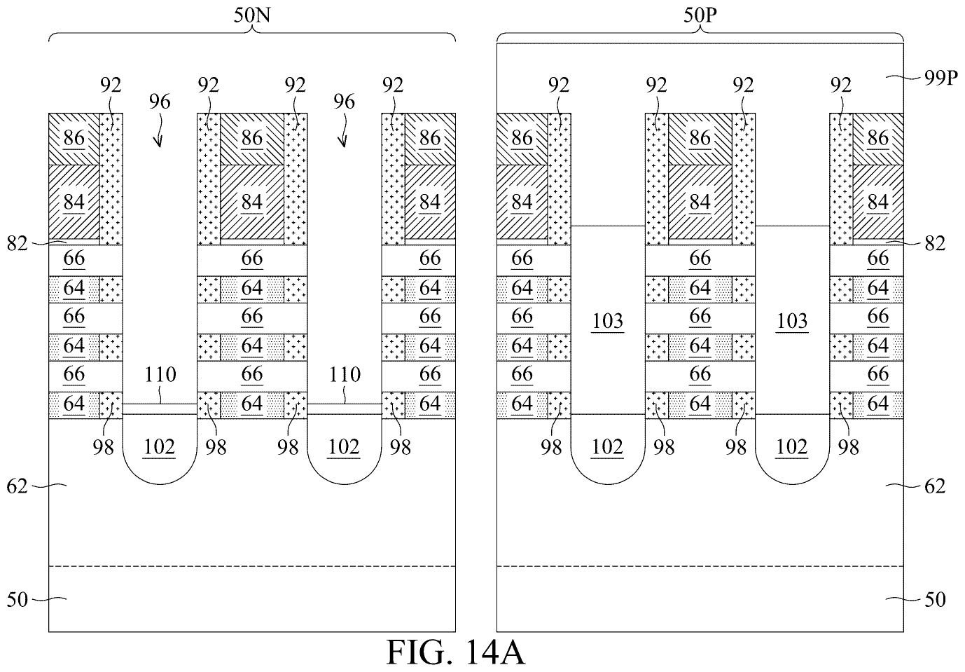

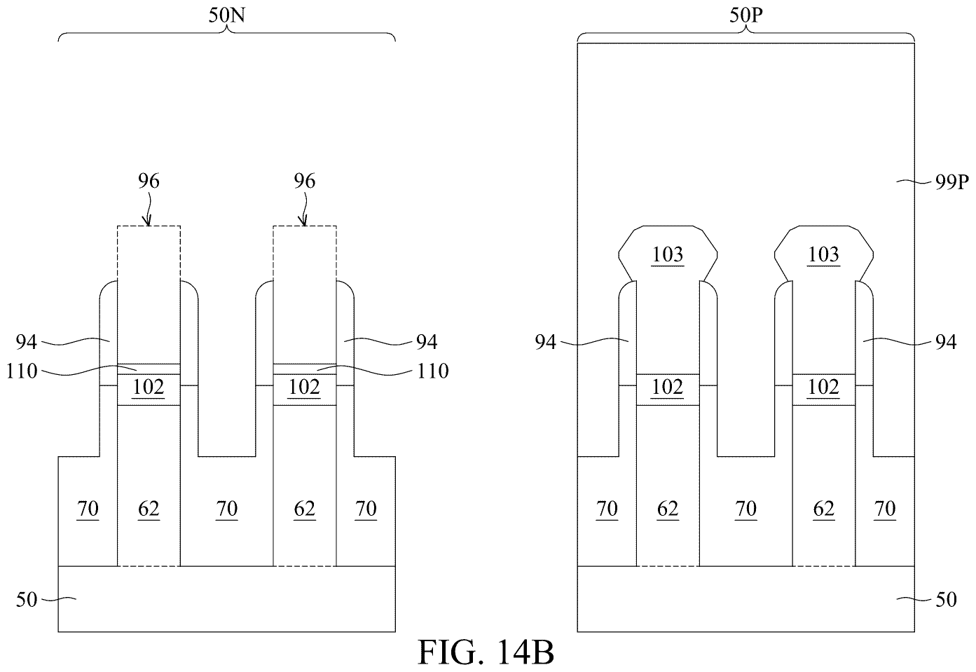

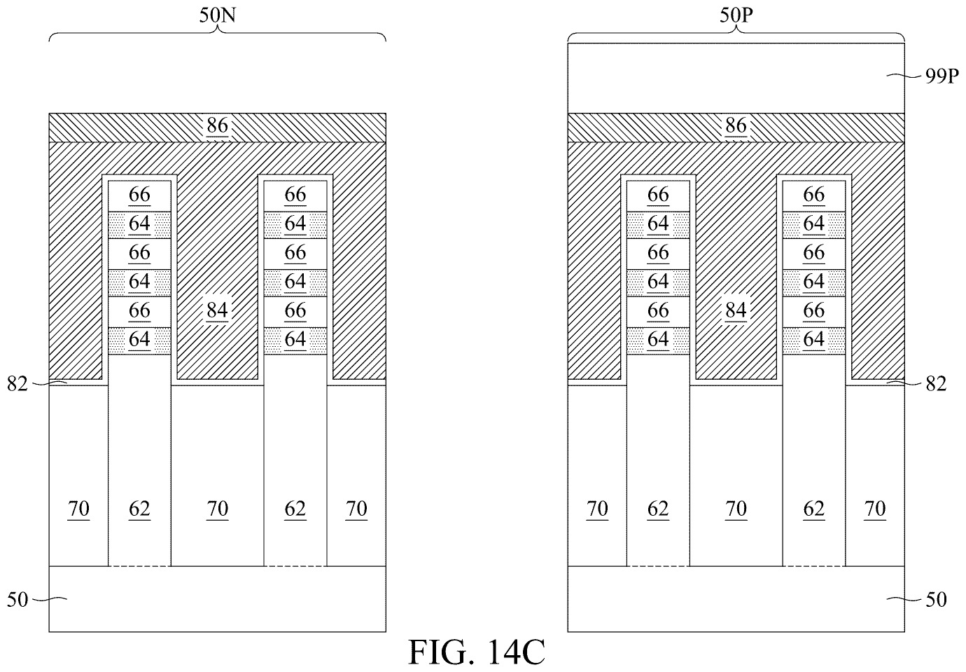

FIGS. 14A-14C, 15A-15C, and 16A-16C illustrate the formation of epitaxial source/drain regions 113 in the n-type region 50N, in accordance with some embodiments. The epitaxial source/drain regions 113 in the n-type region 50N may be referred to as “n-type source/drain regions.” In some embodiments, the epitaxial source/drain regions 113 comprise strain layers 111 and main layers 112, described in greater detail below. In some cases, the strain layers 111 may be considered “first semiconductor material layers” and the main layers 112 may be considered “second semiconductor material layers.” The strain layers 111 and the main layers may be formed of different semiconductor materials and may be doped to different dopant concentrations. During formation of the n-type source/drain regions 113, the p-type region 50P may be covered by a mask 99P, which may be a hard mask, a photoresist mask, or the like. The mask 99P is removed after formation of the n-type source/drain regions 113 using a suitable process, such as an etching process, an ashing process, or the like. In the following discussion of FIGS. 14A through 16C, the described features are within the n-type region 50N unless specifically indicated.

The epitaxial source/drain regions 113 are formed in the source/drain recesses 96 such that each dummy gate 84 of the n-type region 50N is disposed between respective neighboring pairs of the epitaxial source/drain regions 113. In some embodiments, the gate spacers 92 are used to separate the epitaxial source/drain regions 113 from the dummy gates 84, and the inner spacers 98 are used to separate the epitaxial source/drain regions 113 from the nanostructures 64 by an appropriate lateral distance such that the epitaxial source/drain regions 113 do not short out with subsequently formed gates of the resulting n-type nanostructure-FETs.

In FIGS. 14A-14C, bottom spacers 110 are formed on the semiconductor layers 102 in the n-type region 50N, in accordance with some embodiments. Additionally, a spacer layer (not separately illustrated) may also be formed on other horizontal surfaces, such as on portions of the STI regions 70 between the source/drain recesses 96. The bottom spacers 110 may isolate the subsequently-formed n-type source/drain regions from the semiconductor layers 102, and may reduce leakage. The bottom spacers 110 may be formed by conformally forming one or more dielectric material(s) over the semiconductor layers 102, the fin spacers 94, the gate spacers 92, the STI regions 70, and the masks 86 (if present) or the dummy gates 84, and then subsequently etching the dielectric material(s). Acceptable dielectric materials may include silicon nitride, silicon oxynitride, silicon oxycarbonitride, silicon oxycarbide, silicon carbonitride, silicon oxide, aluminum oxide, hafnium oxide, another insulating material, or the like, which may be formed by a deposition process such as chemical vapor deposition (CVD), atomic layer deposition (ALD), or the like. Any acceptable etch process, such as a dry etch, a wet etch, the like, or a combination thereof, may be performed to pattern the dielectric material(s). The etching may be anisotropic. The etching removes the vertical portions of the dielectric material(s). The dielectric material(s), when etched, have horizontal portions left on the top surfaces of the semiconductor layers 102, thus forming the bottom spacers 110. The bottom spacers 110 may be thin, so as to not occupy excessive space in the source/drain recesses 96. In some embodiments, the thickness of the bottom spacers 110 is in the range of 3 nm to 5 nm.

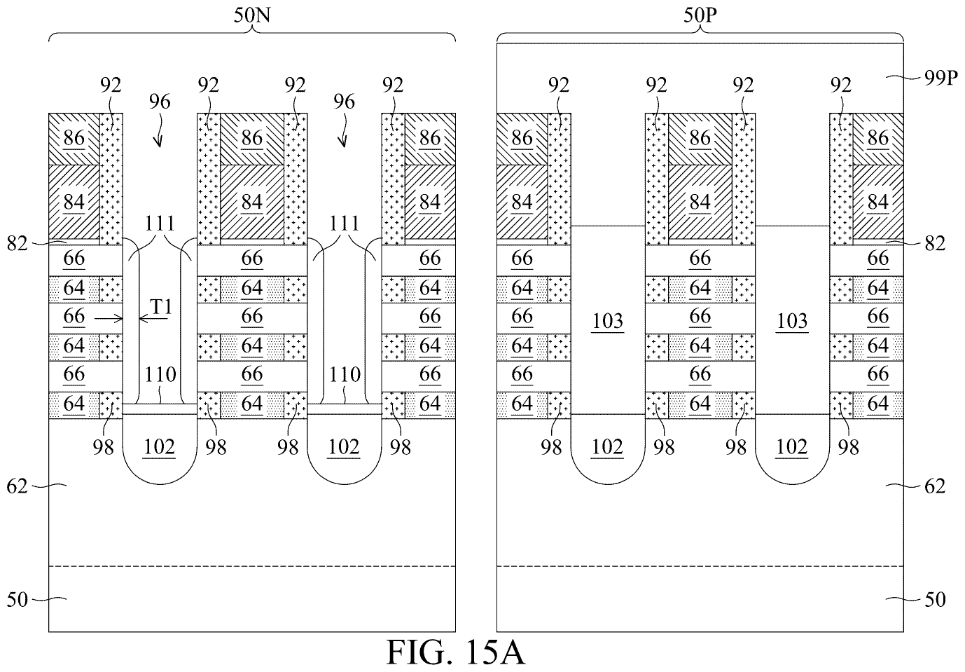

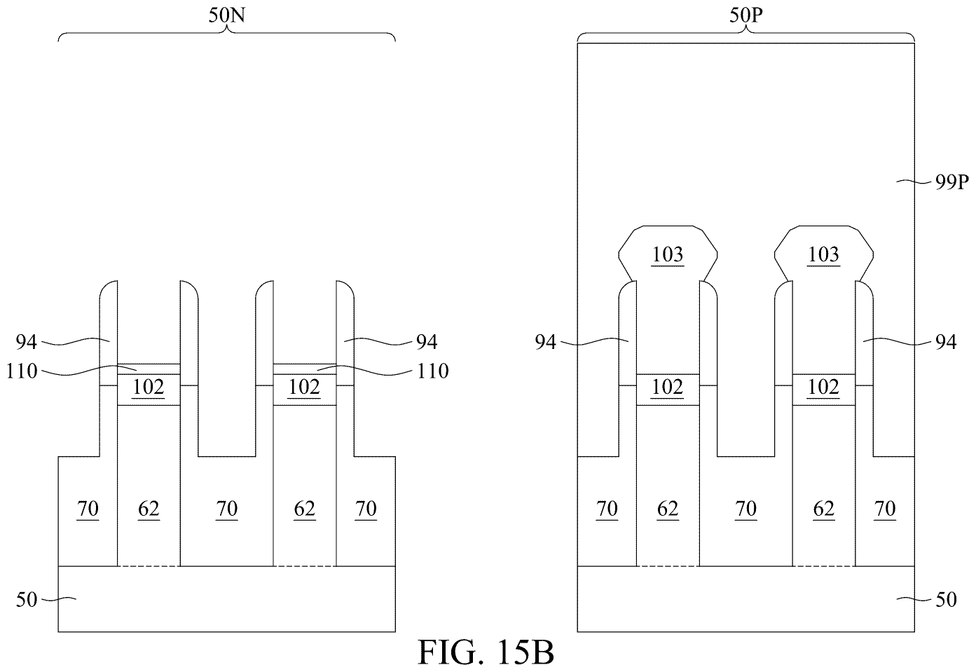

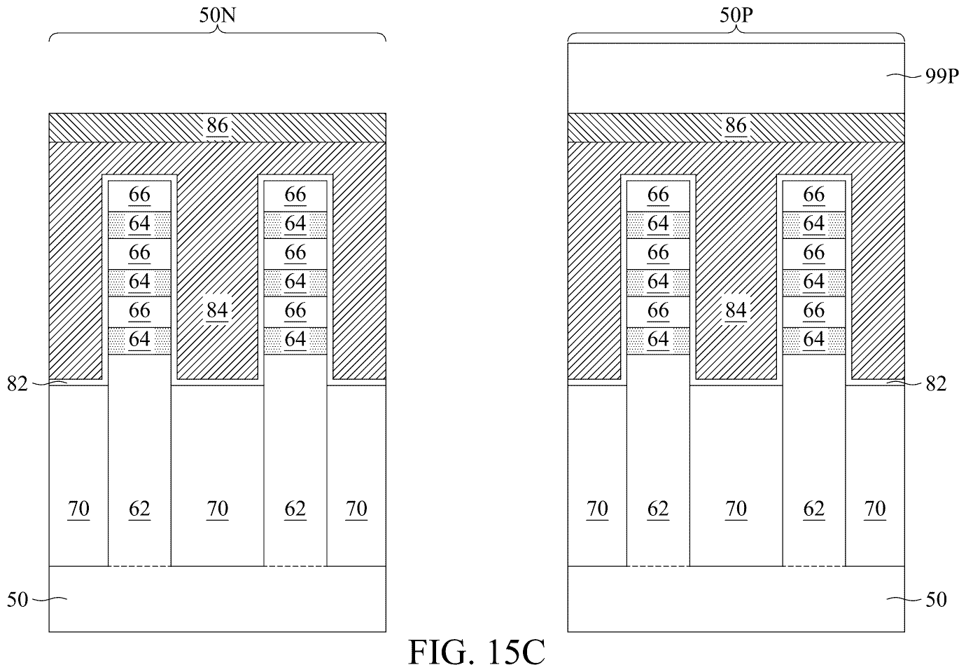

In FIGS. 15A-15C, strain layers 111 are formed on sidewalls of the second nanostructures 66, in accordance with some embodiments. The strain layers 111 are semiconductor layers that extend continuously along sidewalls of the source/drain recesses 96. For example, in some embodiments, a strain layer 111 may cover sidewalls of the second nanostructures 66 within a source/drain recess 96 and cover sidewalls of the inner spacers 98 that are between the second nanostructures 66. A strain layer 111 may extend continuously along surfaces from a sidewall of the second nanostructure 66 that is closest to the substrate 50 to a sidewall of the second nanostructure 66 that is farthest from the substrate 50. In some embodiments, a strain layer 111 may extend continuously along sidewall surfaces from a gate spacer 92 to a bottom spacer 110. In other embodiments, the strain layers 111 do not physically contact the gate spacers 92 and/or the bottom spacers 110.

The strain layers 111 may be formed using an epitaxy process, which may be similar to an epitaxy process described for the semiconductor layers 102, the p-type source/drain regions 103, and/or the main layers 112 (see FIGS. 16A-16C). The epitaxy processes used to form the strain layers 111 are performed such that the strain layers 111 are selectively grown from semiconductor features (e.g., the second nanostructures 66) and do not grow from dielectric features (e.g., the inner spacers 98 and/or the bottom spacers 110). In some embodiments, the strain layers 111 are grown by flowing a semiconductor-containing precursor, an etchant-containing precursor, and/or a dopant-containing precursor in the source/drain recesses 96. The semiconductor-containing precursor and the etchant-containing precursor may be selected from, respectively, the same semiconductor-containing precursors and etchant-containing precursors for growing the semiconductor layers 102, or may include different precursors. In some cases, regions of material that are epitaxially grown on the second nanostructures 66 may merge to form continuous strain layers 111.

The mask 99P substantially prevents growth in the p-type region 50P. The strain layers 111 may comprise a semiconductor material that exerts tensile stress on the second nanostructures 66 (described in greater detail below) as part of the epitaxial source/drain regions 113, with this tensile strain of the second nanostructures 66 improving performance of the resulting n-type nanostructure-FETs. The strain layers 111 may comprise a material such as silicon germanium (SiGe), arsenic-doped silicon germanium (SiGeAs), or the like. In some embodiments, the strain layers 111 comprise between about 15% and about 35% germanium. In some embodiments, the strain layers 111 comprise an impurity concentration that is in the range of about 10²¹ atoms/cm³ to about 10²² atoms/cm³. For example, for embodiments in which the strain layers 111 are arsenic-doped silicon germanium, the strain layers 111 may comprise a concentration of arsenic that is in the range of about 1×10²¹ atoms/cm³ to about 2×10²¹ atoms/cm³. Other concentrations are possible. In some embodiments, the strain layers 111 may be in situ doped during growth. The strain layers 111 may have other compositions than these in other embodiments. In some embodiments, the strain layers 111 have a thickness T1 on sidewalls of the second nanostructures 66 that is in the range of about 4 nm to about 6 nm, though other thicknesses are possible. The strain layers 111 are shown having substantially flat surfaces along the sidewalls of the source/drain recesses 96, but the strain layers 111 may have curved or irregular surfaces in other cases.

In FIGS. 16A-16C, main layers 112 are formed over the strain layers 111 to form epitaxial source/drain regions 113, in accordance with some embodiments. The main layers 112 may be formed by an epitaxy process (subsequently described). The main layers 112 may include any acceptable material appropriate for n-type nanostructure-FETs. For example, the main layers 112 may include materials such as silicon, silicon carbide, phosphorous doped silicon carbide, silicon phosphide (SiP), or the like. The main layers 112 may have surfaces raised from respective upper surfaces of the nanostructures 64/66 and may have facets. The main layers 112 may be formed of a single layer of semiconductor material or may be formed of two or more sublayers of semiconductor materials.

The main layers 112 are epitaxially grown in the source/drain recesses 96 in the n-type region 50N, and cover the strain layers 111. Thus, the strain layers 111 extend between the main layers 112 and the second nanostructures 66. In some cases, the strain layers 111 reduce diffusion of impurities of the main layers 112 into the second nanostructures 66, described in greater detail below. The mask 99P substantially prevents growth in the p-type region 50P. The epitaxy processes used to form the main layers 112 (or epitaxial source/drain regions 113) are performed such that the main layers 112 are selectively grown from the strain layers 111 and do not grow from dielectric features (e.g., the bottom spacers 110). The main layers 112 may be grown by flowing a semiconductor-containing precursor, an etchant-containing precursor, and/or a dopant-containing precursor in the source/drain recesses 96. The semiconductor-containing precursor and the etchant-containing precursor may be selected from, respectively, the same semiconductor-containing precursors and etchant-containing precursors for growing the semiconductor layers 102, or may include different precursors. The dopant-containing precursor contains an appropriate dopant for n-type source/drain regions, such as an arsenic-containing precursor such as arsine (AsH₃), a phosphorus-containing precursor such as diphosphine (P₂H₆) or phosphane (PH₃), or the like. The etchant-containing precursor may be flowed at a slower flow rate when growing the main layers 112 than when growing the semiconductor layers 102, which may cause the main layers 112 to be grown in more of a lateral manner than a bottom-up manner. In some embodiments, the semiconductor-containing precursor is flowed at a flow rate in the range of about 1000 sccm or less, the etchant-containing precursor is flowed at a flow rate in the range of about 1000 sccm or less, and the dopant-containing precursor is flowed at a flow rate in the range of about 1000 sccm or less. The epitaxy process for the main layers 112 may have a faster lateral growth rate and a slower bottom-up growth rate than the epitaxy process for the semiconductor layers 102. As such, the main layers 112 may grow substantially laterally from the strain layers 111. In some embodiments, the epitaxial growth is performed at a temperature in the range of about 400° C. to about 900° C., and at a pressure in the range of about 1 Torr to about 500 Torr. Other precursors or process parameters are possible.

The main layers 112 may have an impurity concentration of between about 10²¹ atoms/cm³ and about 10²² atoms/cm³. For example, for embodiments in which the main layers 112 are silicon phosphide, the phosphorus concentration may be in the range of about 3×10²¹ atoms/cm³ to about 4×10²¹ atoms/cm³. In some embodiments, the main layers 112 have an impurity concentration that is greater than the impurity concentration of the strain layers 111. Other concentrations are possible. In some embodiments, the main layers 112 are in situ doped during growth. In other embodiments, the main layers 112, the nanostructures 64/66, and/or the fins 62 within the n-type region 50N may be implanted with dopants, followed by an anneal.

As a result of the epitaxy processes used to form the main layers 112, upper surfaces of the epitaxial source/drain regions 113 can have facets which expand laterally outward beyond sidewalls of the nanostructures 64/66. In some embodiments, these facets cause adjacent epitaxial source/drain regions 113 of a same nanostructure-FET to merge. In other embodiments, adjacent epitaxial source/drain regions 113 remain separated after the epitaxy process is completed, as illustrated by FIG. 16B. In the illustrated embodiments, the fin spacers 94 are formed on top surfaces of the STI regions 70, thereby blocking the epitaxial growth. In some other embodiments, the fin spacers 94 may cover portions of the sidewalls of the nanostructures 64/66 and/or the fins 62, further blocking the epitaxial growth. In another embodiment, the spacer etch used to form the gate spacers 92 is controlled to not form the fin spacers 94, so as to allow the epitaxial source/drain regions 113 to extend to the surface of the STI region 70. In some embodiments, the epitaxial source/drain regions 113 extend above the top surface of the nanostructures 66. As a result, a top surface of an epitaxial source/drain region 113 is disposed further from the substrate 50 than the top surface of the adjacent nanostructures 66.

As mentioned previously, the use of strain layers 111 as described herein can result in increased tensile strain of the second nanostructures 66 in the n-type region 50N. The strain layers 111 can partially or fully compensate for reduced tensile stress from the main layers 112 due to the presence of the bottom spacers 110. For example, in some cases, little or no epitaxial growth occurs on the dielectric bottom spacers 110, and thus the semiconductor materials of the n-type source/drain regions mostly or entirely grow from the exposed semiconductor material sidewalls within the source/drain recesses 96. For some semiconductor materials, such as silicon phosphide, the exerted tensile stress is improved by having bottom-up epitaxial growth in addition to lateral growth. Thus, the presence of the bottom spacers 110 can result in reduced tensile stress from n-type source/drain regions, which can result in reduced device performance, in some cases.

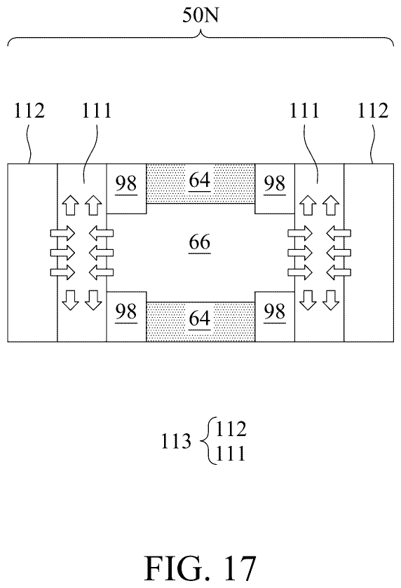

However, the presence of the strain layers 111 as described herein can generate tensile stress that can mitigate the effects of reduced tensile stress from the main layers 112 due to lateral epitaxial growth. The strain layers 111 can recover the tensile strain of the second nanostructures 66 that is lost due to lateral epitaxial growth of the main layers 112. Thus, the strain layers 111 can exert tensile stress on the second nanostructures 66 that can improve device performance. In some cases, device performance may be improved by at least 1%. FIG. 17 illustrates a portion of an n-type region 50N around a second nanostructure 66, in accordance with some embodiments. The second nanostructure 66 may be similar to those shown in FIG. 16A, and the cross-section of FIG. 17 may be similar to that of FIG. 16A. As shown in FIG. 17 by the vertical arrows, the lattice of the strain layers 111 can relax in the vertical direction (e.g., in a direction along the sidewalls of the second nanostructures 66). Because the strain layers 111 have a nonzero Poisson's ratio, a relaxation in the vertical direction results in a contraction in the horizontal direction (e.g., in a direction normal to the sidewalls of the second nanostructures 66) of the strain layers 111. This horizontal contraction of the strain layers 111 results in an overall tensile strain of the second nanostructures 66. In this manner, the performance of an n-type nanostructure-FET may be improved while still allowing for the formation of a bottom spacer 110 that reduces leakage.

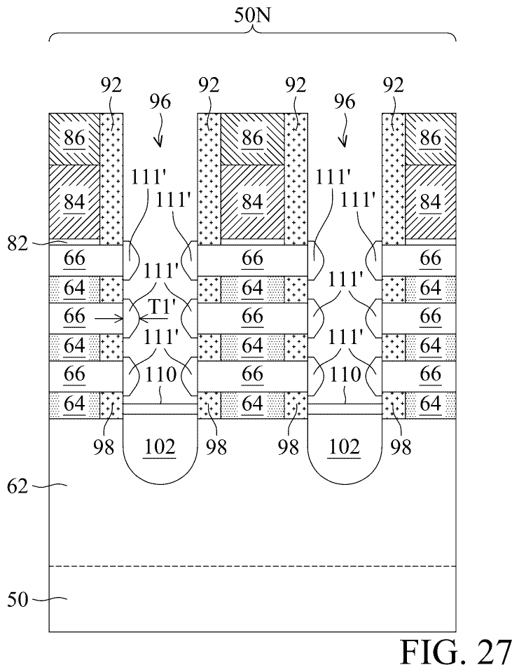

In some cases, a continuous strain layer 111 along the second nanostructures 66 may provide more tensile stress than a separate strain region on each second nanostructures 66. In other embodiments, separate strain regions may be formed instead of a continuous layer, and a non-limiting example is described for FIGS. 27-29 below. In some cases, different semiconductor materials may provide different amounts of tensile strain within the second nanostructures 66. For example, strain layers 111 comprising silicon germanium may provide more tensile strain than strain layers 111 comprising arsenic-doped silicon germanium, in some cases.

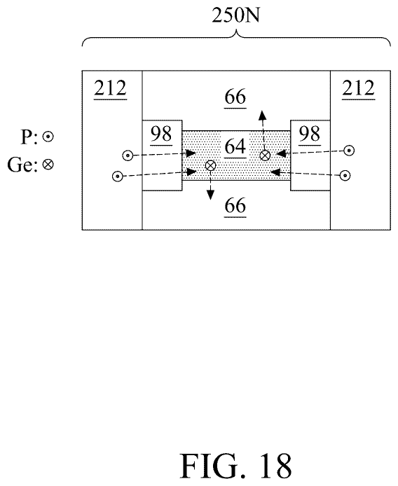

In some cases, the presence of the strain layers 111 can also reduce unwanted diffusion of impurities from the n-type source/drain regions 113 into the second nanostructures 66. As an illustrative example, FIG. 18 illustrates a portion of an n-type region 250N around a first nanostructure 64. The n-type region 250N is similar to the n-type region 50N of FIG. 16A, except that strain layers 111 are not formed. Accordingly, only main layers 212 are formed in the n-type region 250N, which may be similar to the main layers 112 of the n-type region 50N of FIG. 16A. For example, the main layers 212 may be silicon phosphide. The first nanostructure 64 of FIG. 18 may be similar to those shown in FIG. 16A. For example, the first nanostructure of FIG. 18 may be silicon germanium.

As shown in FIG. 18, when the strain layers 111 are not present, phosphorus (P) atoms in the main layers 212 can diffuse through the inner spacers 98 and into the first nanostructures 64. The phosphorus atoms in the first nanostructures 64 can facilitate diffusion of germanium atoms out of the first nanostructures 64 and into the second nanostructures 66. The presence of germanium atoms in the second nanostructures 66 can have undesirable effects, such as reducing etching selectivity between the first nanostructures 64 and the second nanostructures 66. Additionally, the presence of germanium atoms in the second nanostructures 66 can increase resistance within the second nanostructures 66, which can negatively impact device performance.

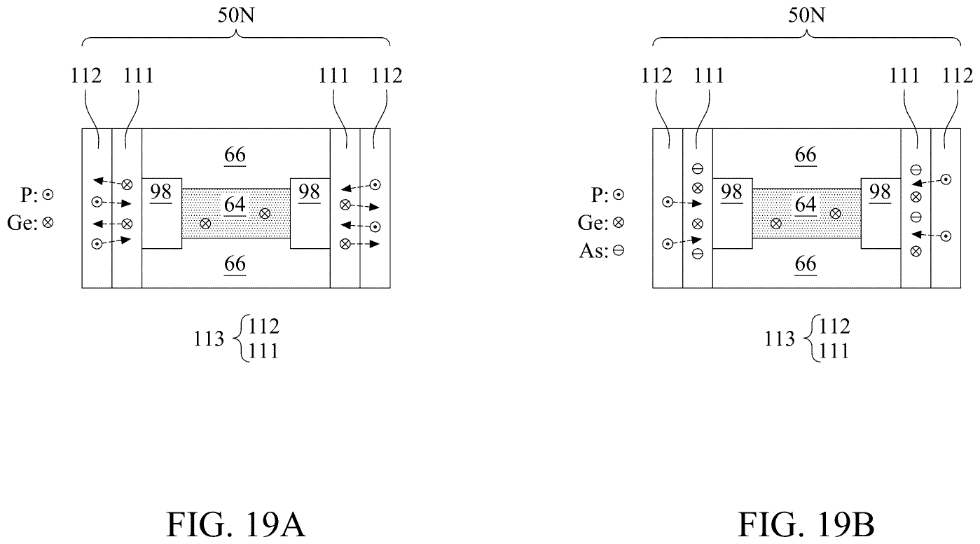

FIGS. 19A and 19B illustrate portions of n-type regions 50N comprising strain layers 111, in accordance with some embodiments. For example, the strain layers 111 are formed between main layers 112 and the inner spacers 98, similar to the structure shown in FIG. 16A. The main layers 112 may be similar to those described previously for FIGS. 16A-C. For example, the main layers 112 may be silicon phosphide. FIG. 19A illustrates strain layers 111 comprising silicon germanium, and FIG. 19B illustrates strain layers 111 comprising arsenic-doped silicon germanium.

As shown in FIG. 19A, the presence of the SiGe strain layers 111 reduces diffusion of phosphorus atoms from the main layers 112 into the first nanostructures 64. The phosphorus atoms that diffuse from the main layers 112 into the strain layers 111 facilitate corresponding diffusion of germanium atoms from the strain layers 111 into the main layers 112. This effective exchange of phosphorus atoms and germanium atoms can result in less diffusion of phosphorus atoms out of the strain layers 111, “blocking” the diffusion of phosphorus atoms into the first nanostructures 64. With less phosphorus atoms diffusing into the first nanostructures 64, the germanium atoms in the first nanostructures 64 are less likely to diffuse out of the first nanostructures 64 and into the second nanostructures 66. Thus, undesirable effects such as reduced etching selectivity and increased resistance as described for FIG. 18 may be avoided.

As shown in FIG. 19B, the presence of the SiGeAs strain layers 111 reduces diffusion of phosphorus atoms from the main layers 112 into the first nanostructures 64, and also reduces diffusion of the germanium atoms from the strain layers 111 into the main layers 112. Similar to the SiGe strain layers 111 of FIG. 19A, the phosphorus atoms that diffuse from the main layers 112 into the strain layers 111 are “blocked” by the germanium atoms in the strain layers 111. However, the presence of arsenic atoms in the SiGeAs strain layers 111 reduces the diffusion of germanium atoms out of the strain layers 111. The presence of germanium atoms in the SiGeAs strain layers 111 also can reduce diffusion of arsenic atoms out of the strain layers 111. Thus, diffusion of phosphorus atoms into the first nanostructures 64 can be reduced, and diffusion of germanium atoms and arsenic atoms into the main layers 112 can be reduced. In some cases, germanium atoms (and/or arsenic atoms) diffusing into the main layers 112 can increase resistance of the main layers 112. Thus, in some cases, the use of arsenic-doped silicon germanium strain layers 111 instead of silicon germanium strain layers 111 can result in improved resistance of the n-type source/drain regions 113 when strain layers 111 are present. This improved resistance may be in addition to benefits similar to those described for SiGe strain layers 111 in FIG. 19A.

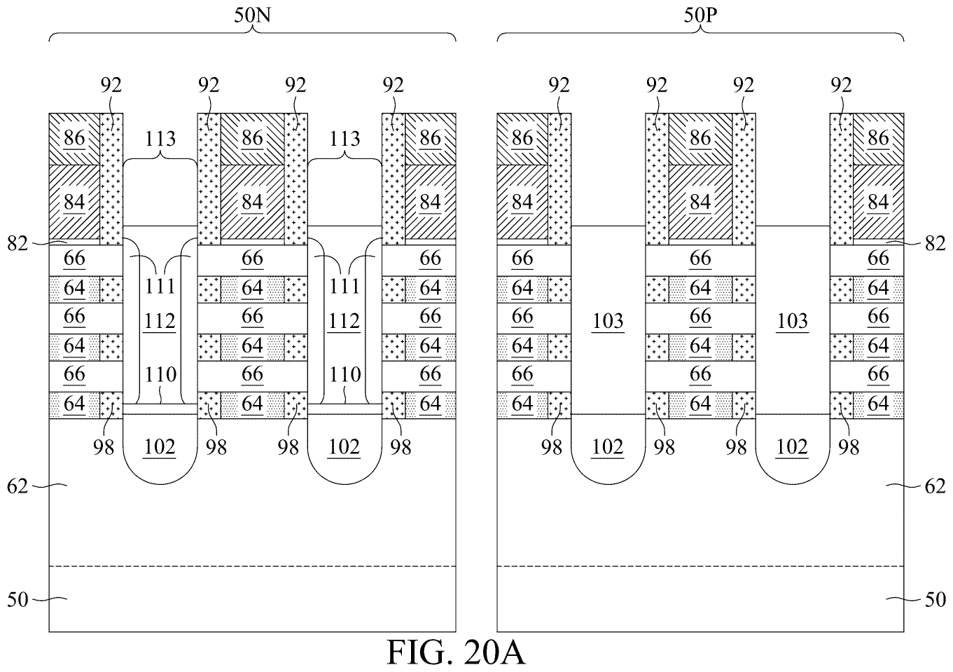

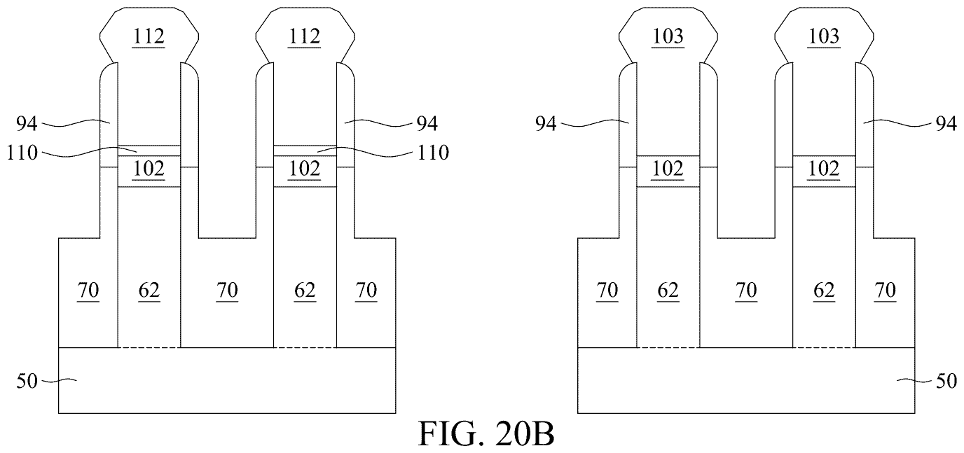

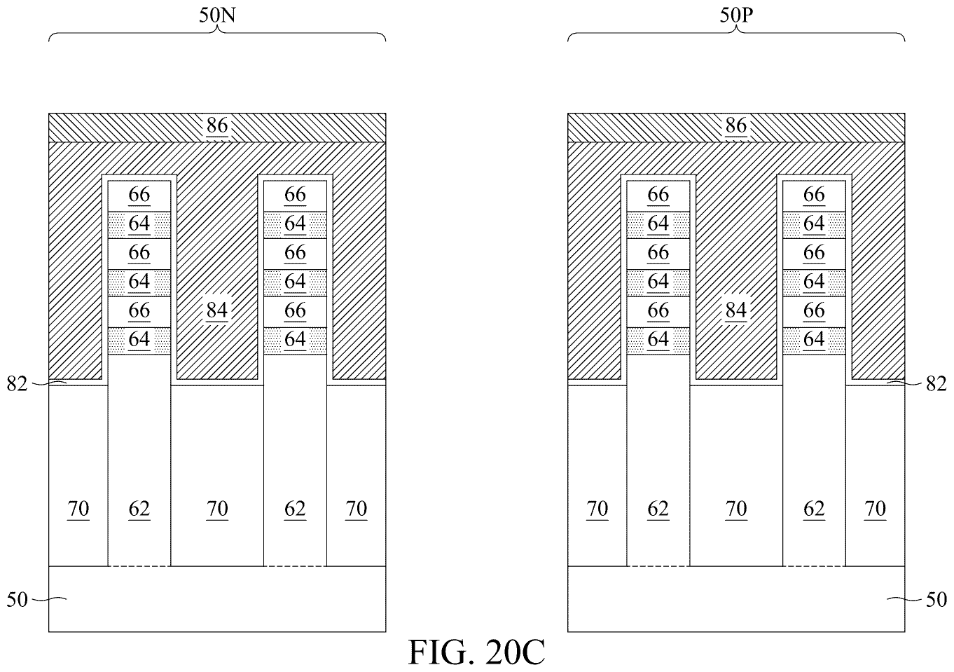

Turning to FIGS. 20A-20C, the n-type region 50N is shown after formation of the epitaxial source/drain regions 113, and the p-type region 50P is shown after formation of the epitaxial source/drain regions 103, in accordance with some embodiments. The structures shown in FIGS. 20A-20C may follow the process steps described above for FIGS. 13A-16C. For example, after forming the epitaxial source/drain regions 113, the mask 99P may be removed from the p-type region 50P using a suitable etching or ashing process. In other embodiments in which the epitaxial source/drain regions 103 are formed after the epitaxial source/drain regions 113, FIGS. 20A-20C may show the structure after removal of the mask 99N, for example. The epitaxial source/drain regions 103 and the epitaxial source/drain regions 113 may be collectively referred to as source/drain regions 103/113 herein.

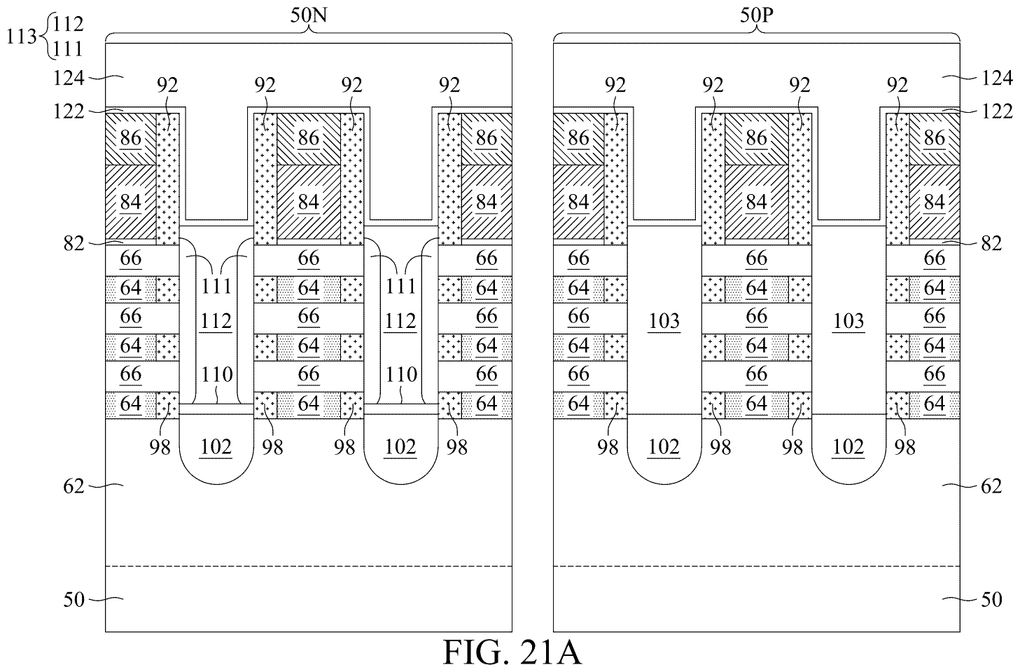

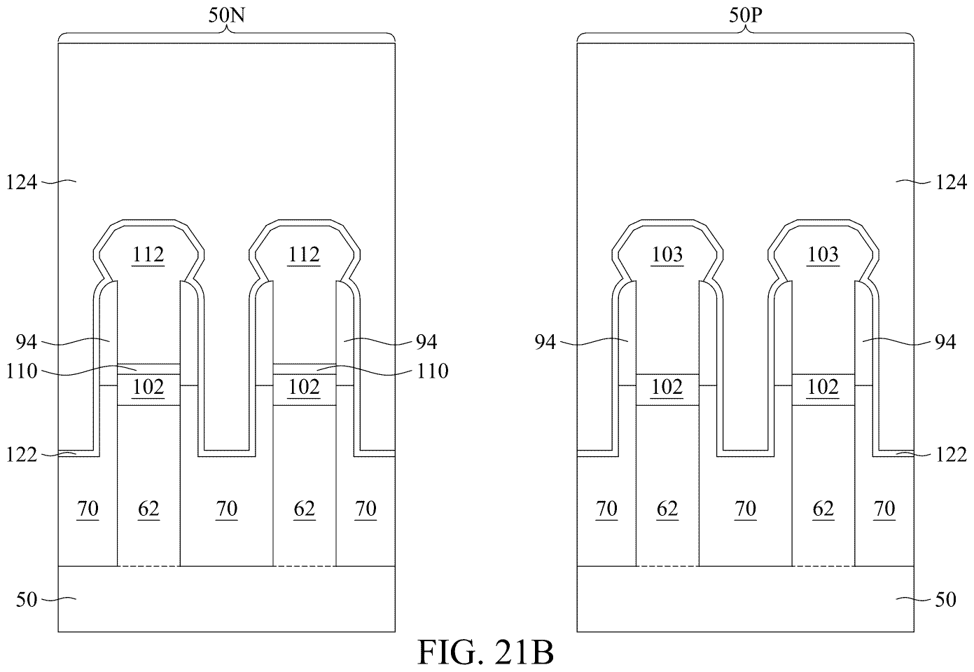

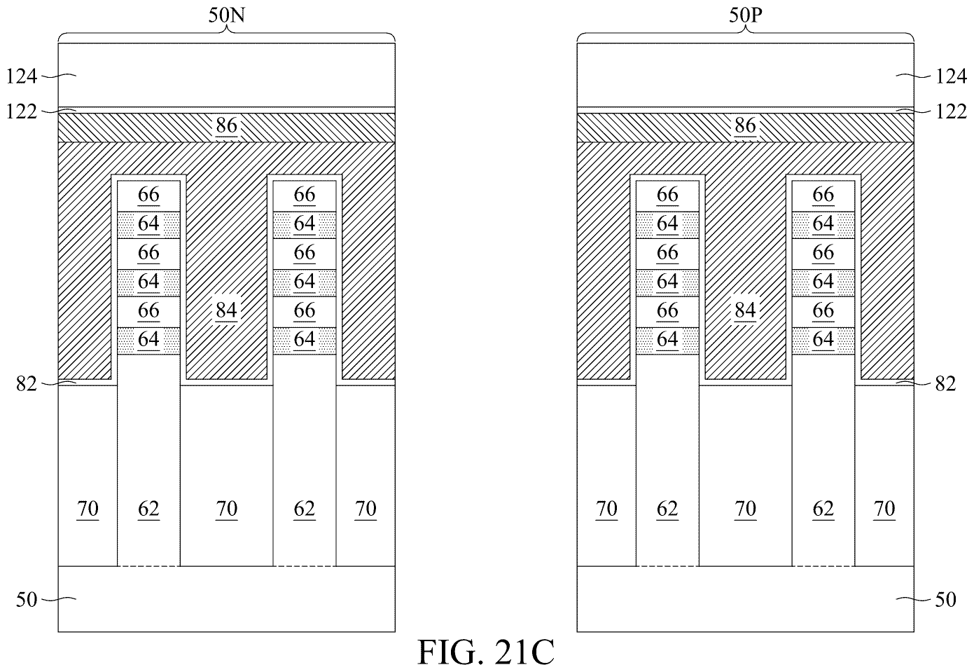

In FIGS. 21A-21C, a first ILD 124 is deposited over the epitaxial source/drain regions 103, the epitaxial source/drain regions 113, the fin spacers 94, the gate spacers 92, the masks 86 (if present), and/or the dummy gates 84. The first ILD 124 may be formed of a dielectric material, which may be deposited by any suitable method, such as CVD, plasma-enhanced CVD (PECVD), or FCVD. Suitable dielectric materials may include silicon oxide, phospho-silicate glass (PSG), boro-silicate glass (BSG), boron-doped phospho-silicate glass (BPSG), undoped silicate glass (USG), or the like. Other insulation materials formed by any acceptable process may be used.

In some embodiments, a contact etch stop layer (CESL) 122 is formed between the first ILD 124 and the epitaxial source/drain regions 103, the epitaxial source/drain regions 113, the fin spacers 94, the gate spacers 92, the masks 86 (if present), and/or the dummy gates 84. The CESL 122 may be formed of a dielectric material having a high etching selectivity from the etching of the first ILD 124, such as silicon nitride, silicon oxide, silicon oxynitride, a combination thereof, or the like, which may be formed using any suitable deposition process, such as CVD, ALD, or the like.

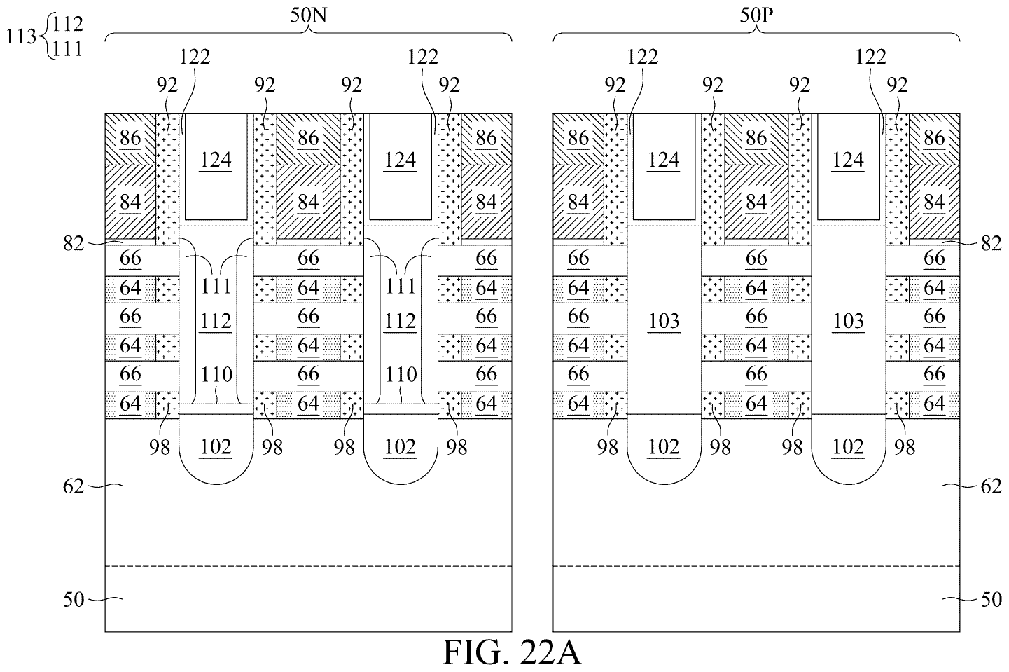

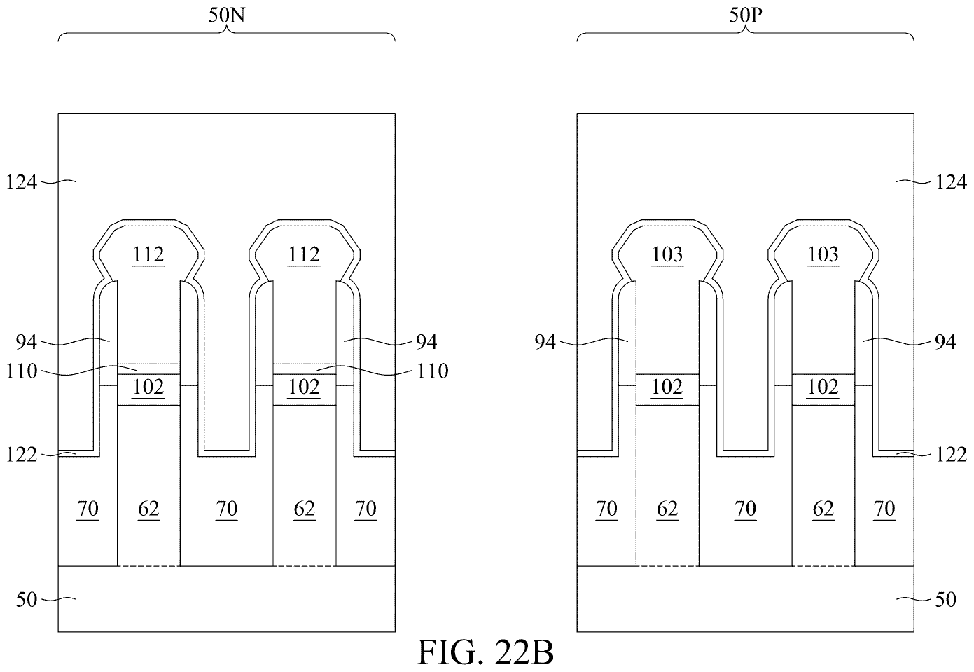

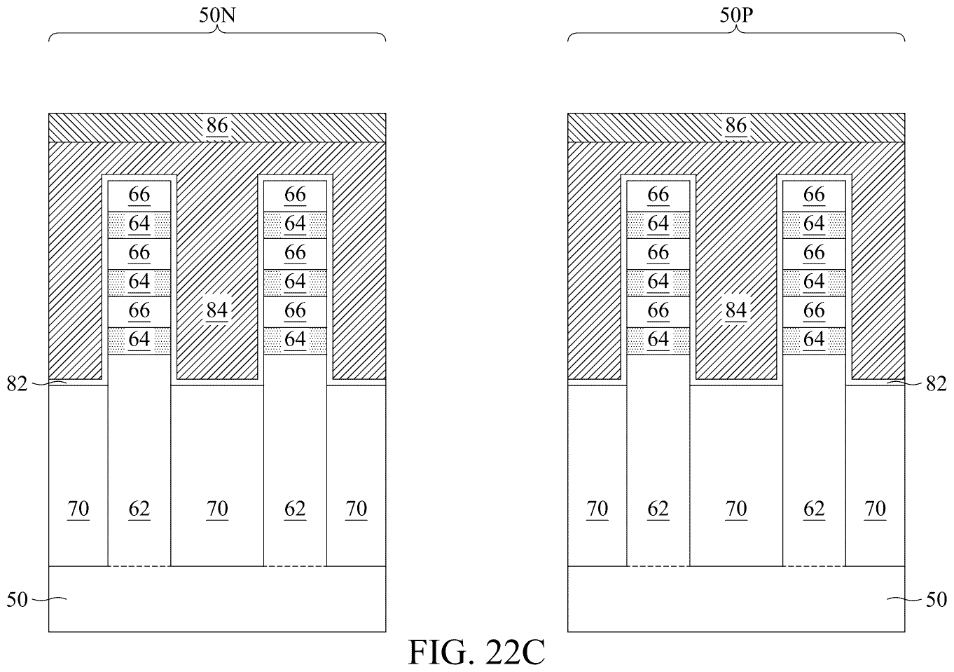

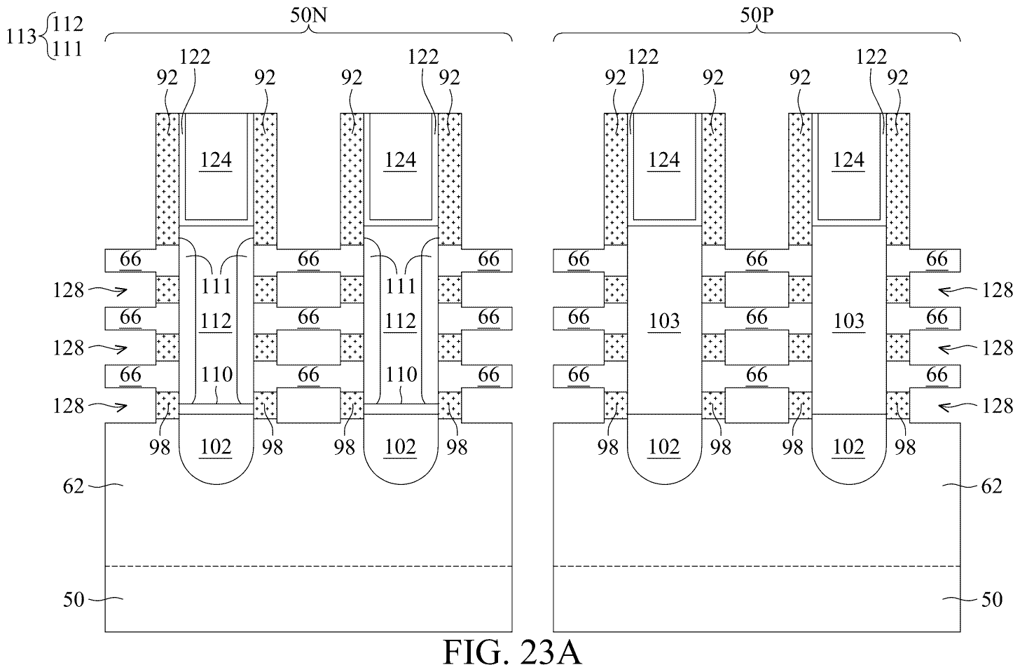

In FIGS. 22A-22C, a removal process is performed to level the top surfaces of the first ILD 124 with the top surfaces of the gate spacers 92 and the masks 86 (if present) or the dummy gates 84. In some embodiments, the removal process comprises a planarization process such as a chemical mechanical polish (CMP), a grinding process, an etch-back process, a combination thereof, or the like. The planarization process may also remove the masks 86 on the dummy gates 84, and portions of the gate spacers 92 along sidewalls of the masks 86. After the planarization process, top surfaces of the first ILD 124, the gate spacers 92, and the masks 86 (if present), and/or the dummy gates 84 are substantially level or coplanar (within process variations). Accordingly, the top surfaces of the masks 86 (if present) and/or the dummy gates 84 may be exposed through the first ILD 124.

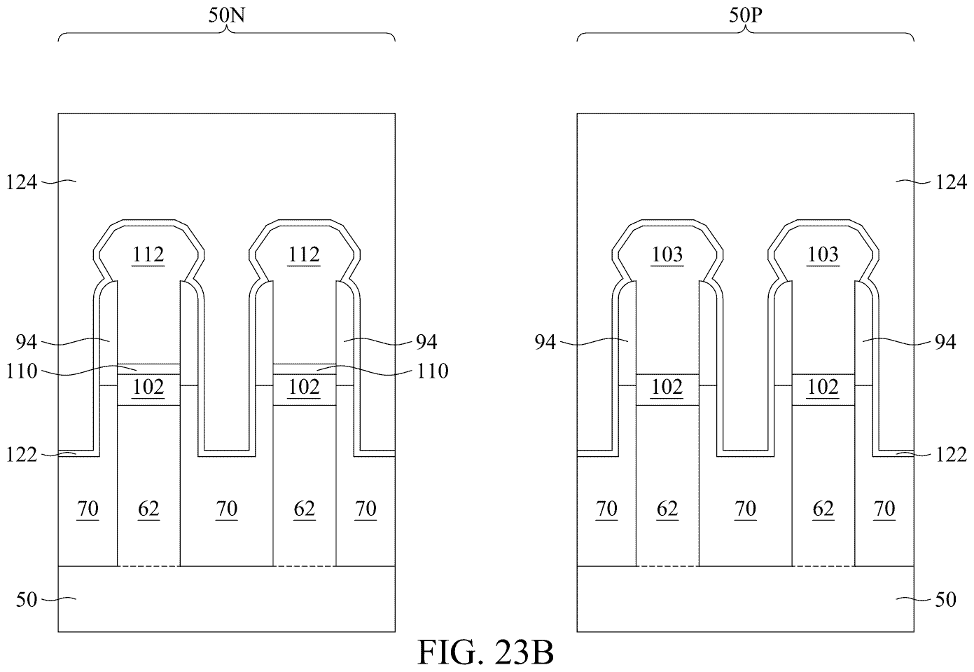

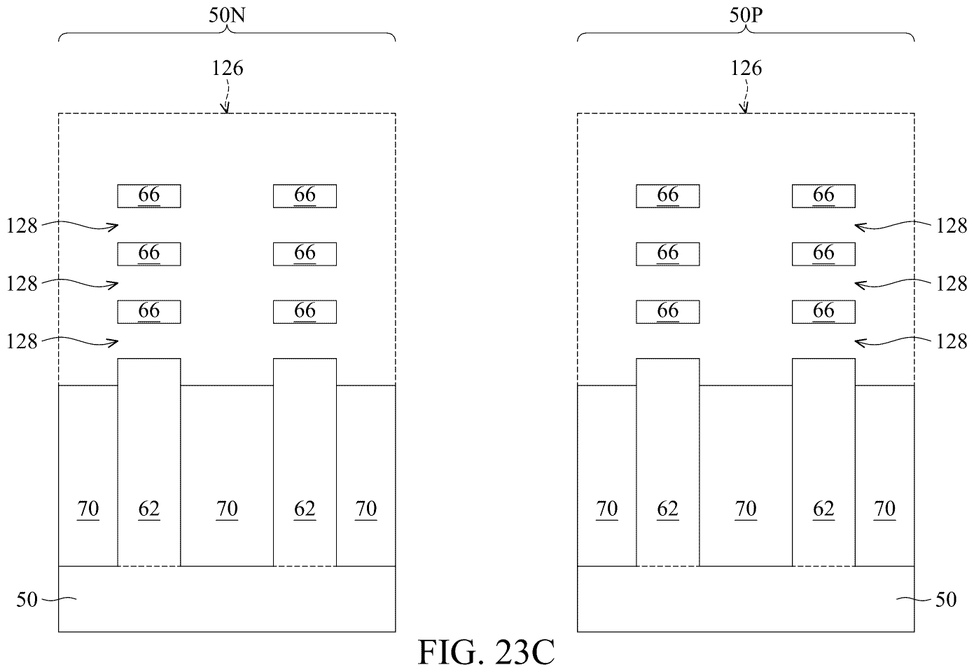

In FIGS. 23A-23C, the masks 86 (if present) and the dummy gates 84 are removed in one or more etching steps, such that recesses 126 are formed between the gate spacers 92. Portions of the dummy dielectrics 82 in the recesses 126 are also removed. In some embodiments, the dummy gates 84 and the dummy dielectrics 82 are removed by an anisotropic dry etch process. For example, the etching process may include a dry etch process using reaction gas(es) that selectively etch the material of the dummy gates 84 at a faster rate than the materials of the first ILD 124 and the gate spacers 92. Each recess 126 exposes and/or overlies portions of nanostructures 64/66, which act as the channel regions in subsequently completed nanostructure-FETs. Portions of the nanostructures 64/66 which act as the channel regions are disposed between neighboring pairs of the epitaxial source/drain regions 113 in the n-type region 50N or between neighboring pairs of the epitaxial source/drain regions 103 in the p-type region 50P. During the removal, the dummy dielectrics 82 may be used as etch stop layers when the dummy gates 84 are etched. The dummy dielectrics 82 may then be removed after the removal of the dummy gates 84.

The remaining portions of the first nanostructures 64 are then removed to form openings 128 in regions between the second nanostructures 66. The remaining portions of the first nanostructures 64 can be removed by any acceptable etch process that selectively etches the material of the first nanostructures 64 at a faster rate than the material of the second nanostructures 66. The etching may be isotropic. For example, when the first nanostructures 64 are formed of silicon germanium and the second nanostructures 66 are formed of silicon, the etch process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the second nanostructures 66 and expand the openings 128. Hereinafter, the second nanostructures 66 may be referred to as nanostructures 66, and the nanostructures 66 over each fin 62 may be referred to as “stacks” of nanostructures 66.

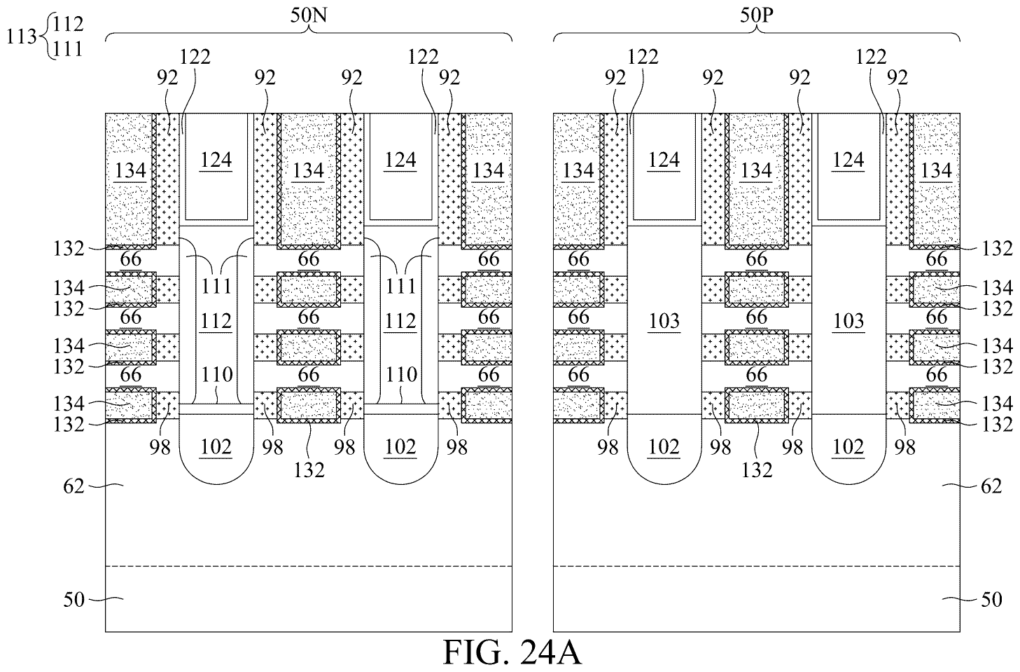

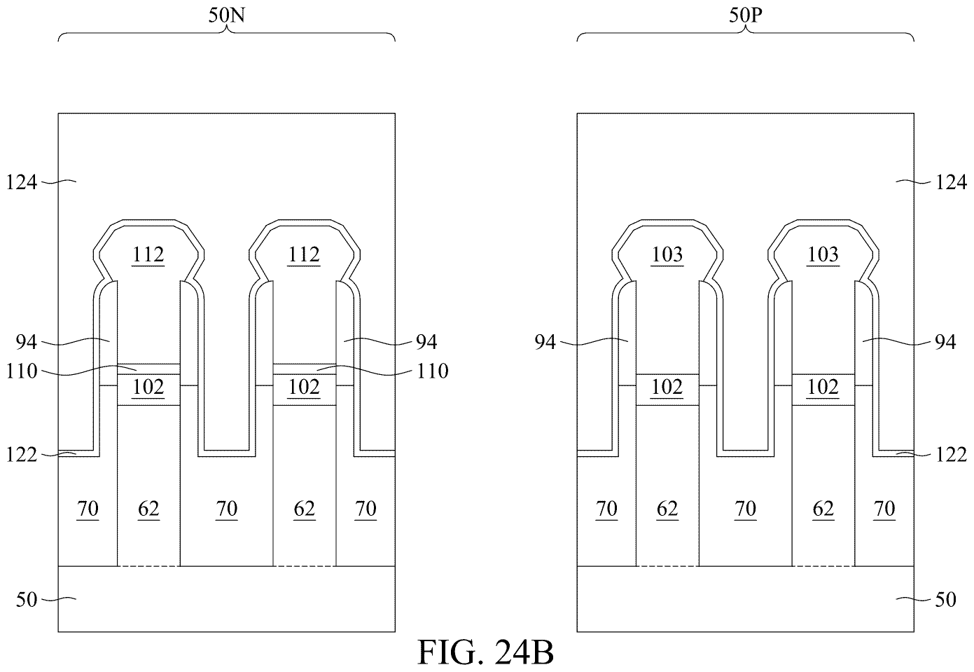

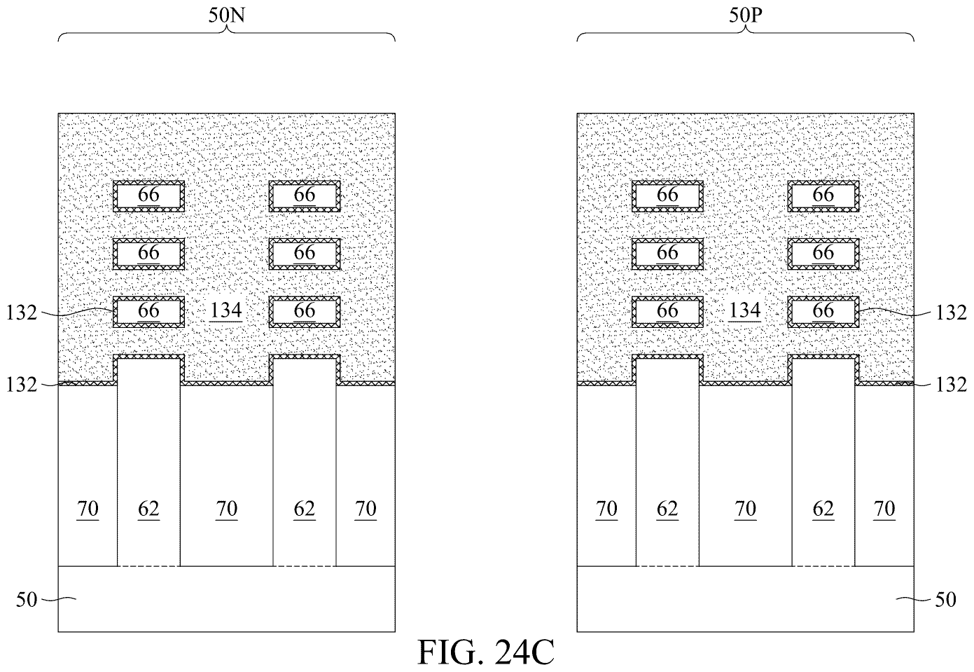

In FIGS. 24A-24C, gate dielectrics 132 and gate electrodes 134 are formed for replacement gates. Each respective pair of a gate dielectric 132 and a gate electrode 134 may be collectively referred to as a “gate structure” or a “gate stack.” Each gate structure is wrapped around a channel region of a nanostructure 66, such that the gate structure extends along sidewalls, a bottom surface, and a top surface of the nanostructure 66. Some of the gate structures also extend along sidewalls and/or a top surface of a fin 62.

The gate dielectrics 132 include one or more gate dielectric layer(s) disposed on the sidewalls and/or the top surfaces of the fins 62; on the top surfaces, the sidewalls, and the bottom surfaces of the channel regions of the nanostructures 66; on the sidewalls of the inner spacers 98 adjacent the source/drain regions 103/113; and on the sidewalls of the gate spacers 92. The gate dielectrics 132 may be formed of an oxide such as silicon oxide or a metal oxide, a silicate such as a metal silicate, combinations thereof, multi-layers thereof, or the like. Additionally or alternatively, the gate dielectrics 132 may be formed of a high-k dielectric material (e.g., dielectric materials having a k-value greater than about 7.0), such as a metal oxide or a silicate of hafnium, aluminum, zirconium, lanthanum, manganese, barium, titanium, lead, and combinations thereof. The dielectric material(s) of the gate dielectrics 132 may be formed by molecular-beam deposition (MBD), ALD, PECVD, or the like. Although single-layered gate dielectrics 132 are illustrated, the gate dielectrics 132 may include any number of interfacial layers and any number of main layers. For example, the gate dielectrics 132 may include an interfacial layer and an overlying high-k dielectric layer.

The gate electrodes 134 include one or more gate electrode layer(s) disposed over the gate dielectrics 132. The gate electrodes 134 may be formed of a metal-containing material such as titanium nitride, titanium oxide, tantalum nitride, tantalum carbide, tungsten, cobalt, ruthenium, aluminum, combinations thereof, multi-layers thereof, or the like. Although single-layered gate electrodes 134 are illustrated, the gate electrodes 134 may include any number of work function tuning layers, any number of barrier layers, any number of glue layers, and a fill material.

As an example to form the gate structures, one or more gate dielectric layer(s) may be deposited in the recesses 126 and the openings 128. The gate dielectric layer(s) may also be deposited on the top surfaces of the first ILD 124, the CESL 122, and the gate spacers 92. Subsequently, one or more gate electrode layer(s) may be deposited on the gate dielectric layer(s), and in the remaining portions of the recesses 126 and the openings 128. A removal process may then be performed to remove the excess portions of the gate dielectric layer(s) and the gate electrode layer(s), which excess portions are over the top surfaces of the first ILD 124, the CESL 122, and the gate spacers 92. In some embodiments, a planarization process such as a chemical mechanical polish (CMP), an etch-back process, combinations thereof, or the like may be utilized. The gate dielectric layer(s), after the removal process, have portions left in the recesses 126 and the openings 128 (thus forming the gate dielectrics 132). The gate electrode layer(s), after the removal process, have portions left in the recesses 126 and the openings 128 (thus forming the gate electrodes 134). When a planarization process it utilized, the top surfaces of the gate spacers 92, the CESL 122, the first ILD 124, the gate dielectrics 132, and the gate electrodes 134 are level or coplanar (within process variations).

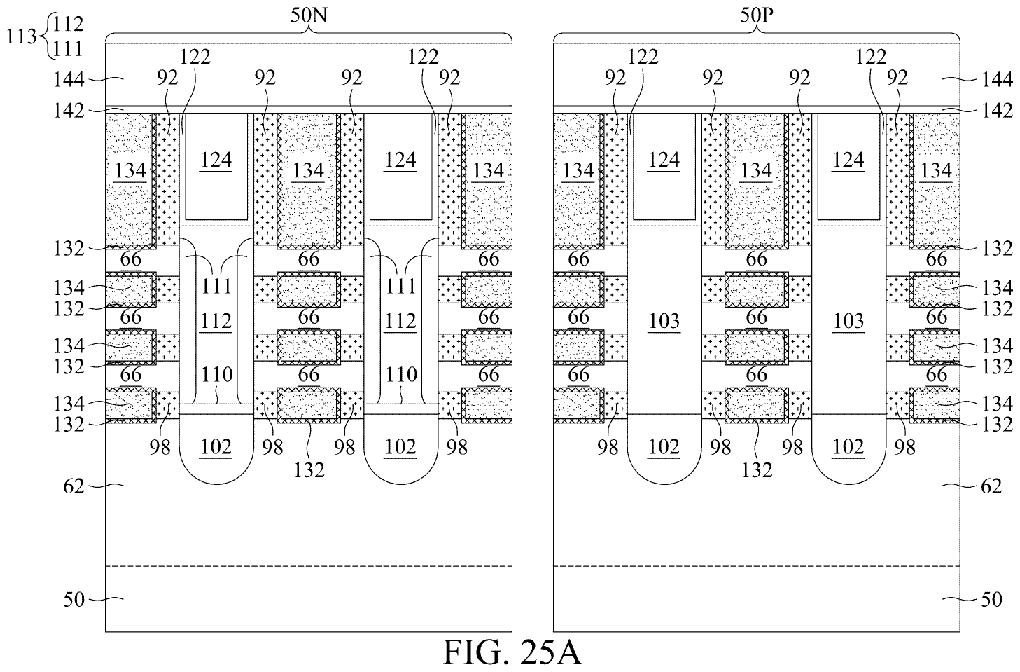

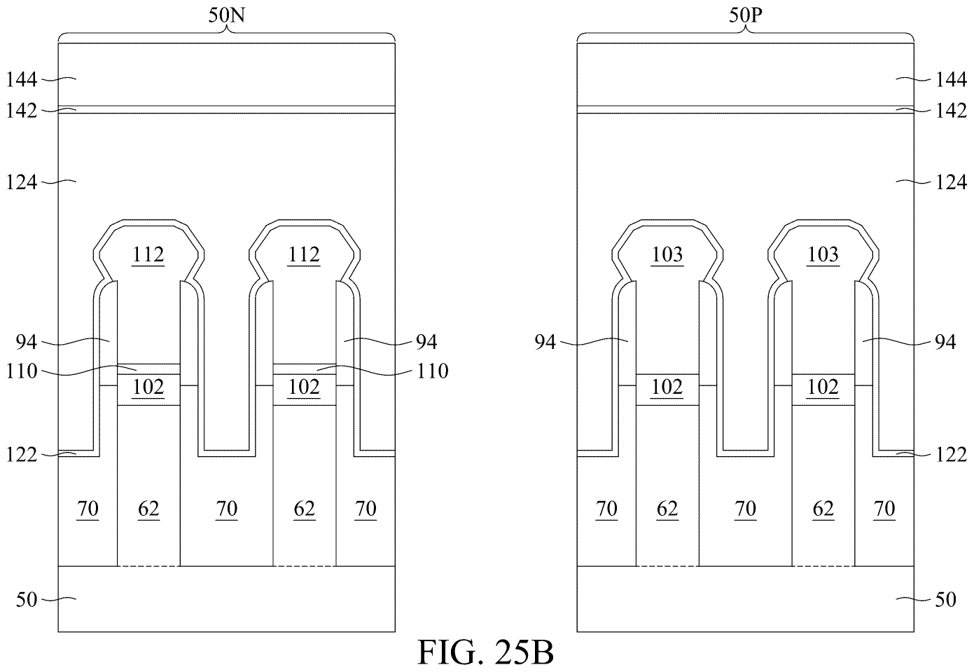

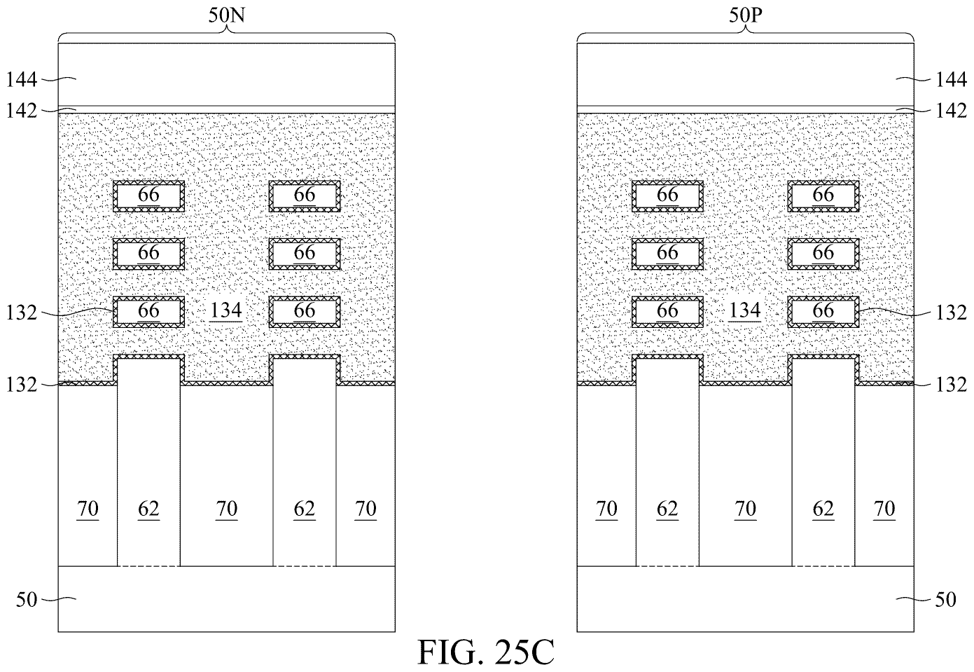

In FIGS. 25A-25C, a second ILD 144 is deposited over the gate spacers 92, the CESL 122, the first ILD 124, the gate dielectrics 132, and the gate electrodes 134. In some embodiments, the second ILD 144 is a flowable film formed by a flowable CVD method. In some embodiments, the second ILD 144 is formed of a dielectric material such as PSG, BSG, BPSG, USG, or the like, which may be formed by any suitable deposition process, such as CVD, PECVD, or the like.

In some embodiments, an etch stop layer (ESL) 142 is formed between the second ILD 144 and the gate spacers 92, the CESL 122, the first ILD 124, the gate dielectrics 132, and the gate electrodes 134. The ESL 142 may be formed of a dielectric material having a high etching selectivity from the etching of the second ILD 144, such as silicon nitride, silicon oxide, silicon oxynitride, or the like, which may be formed by any suitable deposition process, such as CVD, ALD, or the like.

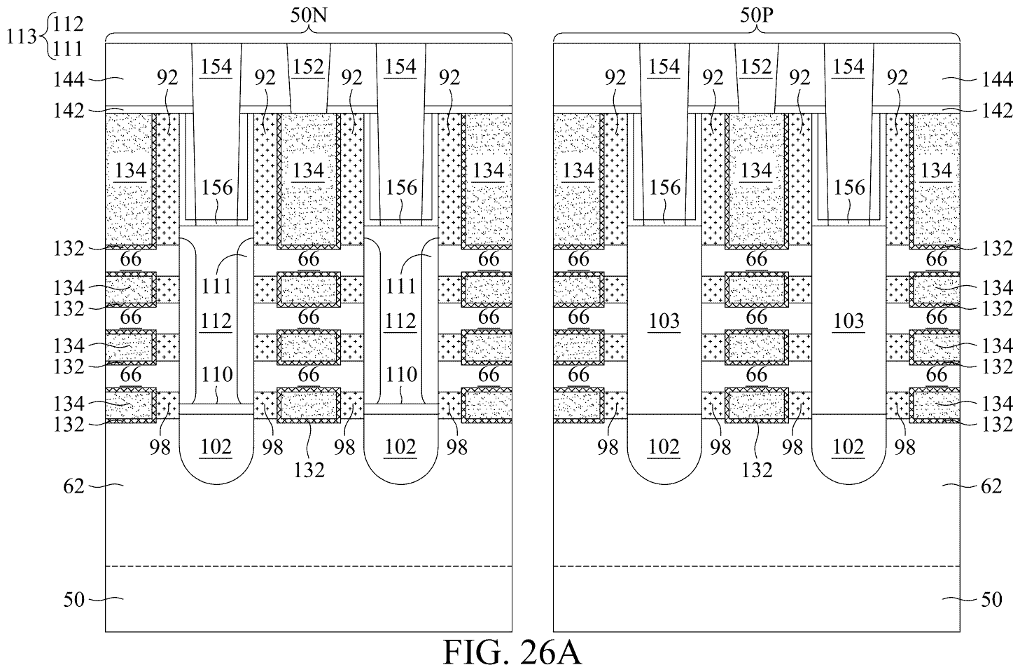

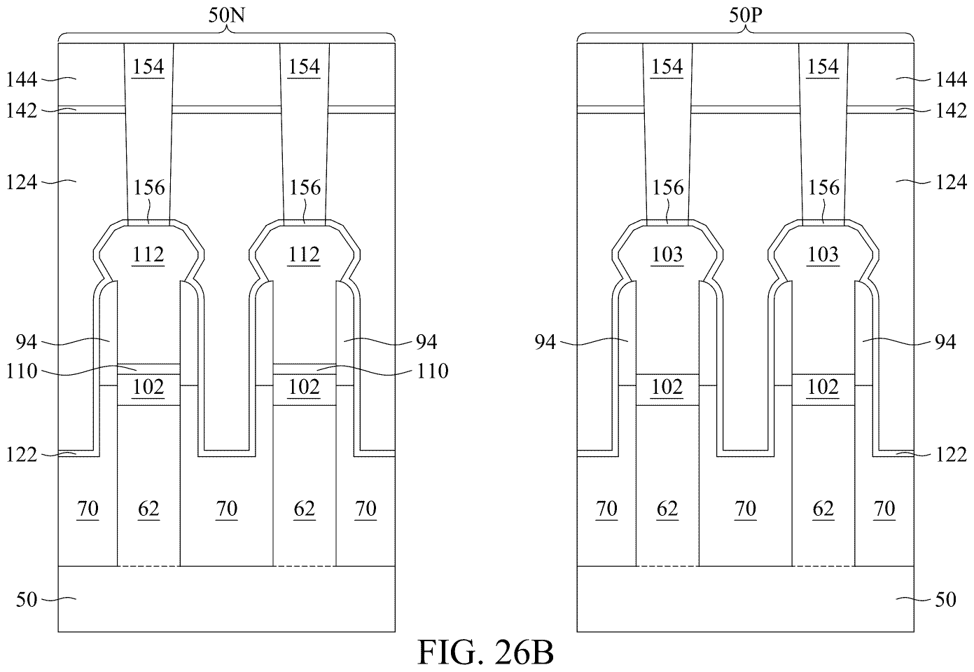

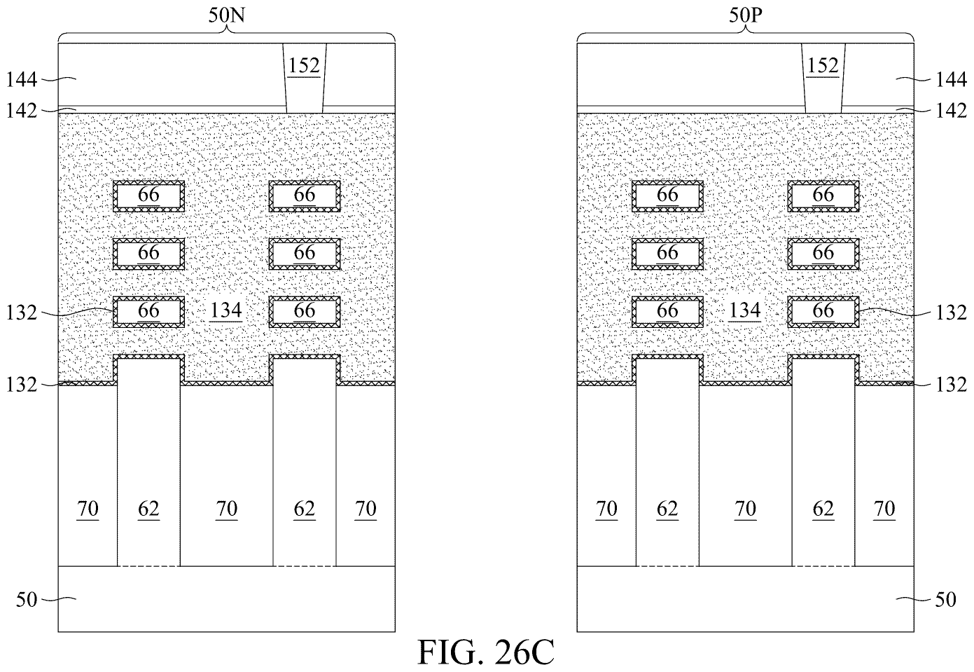

In FIGS. 26A-26C, gate contacts 152 and source/drain contacts 154 are formed to contact, respectively, the gate electrodes 134 and the source/drain regions 103/113. The gate contacts 152 may be physically and electrically coupled to the gate electrodes 134. The source/drain contacts 154 may be physically and electrically coupled to the source/drain regions 103/113.

As an example to form the gate contacts 152 and the source/drain contacts 154, openings for the gate contacts 152 are formed through the second ILD 144 and the ESL 142, and openings for the source/drain contacts 154 are formed through the second ILD 144, the ESL 142, the first ILD 124, and the CESL 122. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 144. The remaining liner and conductive material form the gate contacts 152 and the source/drain contacts 154 in the openings. The gate contacts 152 and the source/drain contacts 154 may be formed in distinct processes, or may be formed in the same process. Although shown as being formed in the same cross-sections, it should be appreciated that each of the gate contacts 152 and the source/drain contacts 154 may be formed in different cross-sections, which may avoid shorting of the contacts.

Optionally, metal-semiconductor alloy regions 156 are formed at the interfaces between the source/drain regions 103/113 and the source/drain contacts 154. The metal-semiconductor alloy regions 156 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon germanide regions formed of both a metal silicide and a metal germanide, or the like. The metal-semiconductor alloy regions 156 can be formed before the material(s) of the source/drain contacts 154 by depositing a metal in the openings for the source/drain contacts 154 and then performing a thermal annealing process. The metal can be any metal capable of reacting with the semiconductor materials (e.g., silicon, silicon carbide, silicon germanium, germanium, etc.) of the source/drain regions 103/113 to form a low-resistance metal-semiconductor alloy, such as nickel, cobalt, titanium, tantalum, platinum, tungsten, other noble metals, other refractory metals, rare earth metals, or their alloys. The metal may be formed by a deposition process such as ALD, CVD, PVD, or the like. After the thermal annealing process, a cleaning process, such as a wet clean, may be performed to remove any residual metal from the openings for the source/drain contacts 154, such as from surfaces of the metal-semiconductor alloy regions 156. The material(s) of the source/drain contacts 154 can then be formed on the metal-semiconductor alloy regions 156.

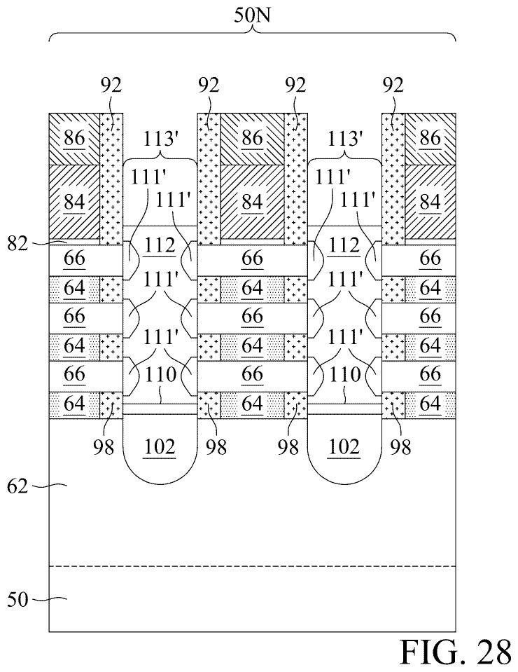

FIGS. 27 and 28 illustrate intermediate steps in the formation of epitaxial source/drain regions 113′ in the n-type region 50N, in accordance with some embodiments. FIGS. 27 and 28 illustrate cross-sectional views of the n-type region 50N during process steps similar to those shown in FIGS. 15A and 16A. The epitaxial source/drain regions 113′ are similar to the epitaxial source/drain regions 113 of FIG. 16A, except that separate strain regions 111′ are formed on respective sidewalls of the second nanostructures 66 instead of continuous strain layers 111 formed over multiple second nanostructures 66. The strain regions 111′ may provide benefits similar to those of the strain layers 111. For example, the strain regions 111′ may exert tensile stress on the second nanostructures 66 and may also reduce diffusion of phosphorus or other impurities into the first nanostructures 64.

FIG. 27 illustrates the formation of strain regions 111′ on the second nanostructures 66, in accordance with some embodiments. As shown in FIG. 27, each strain region 111′ covers a respective sidewall of the second nanostructures 66. The strain regions 111′ are separated and adjacent strain regions 111′ do not physically contact or merge together. In some embodiments, a strain region 111′ may have height that is about the same as or greater than a thickness of the adjacent second nanostructure 66. For example, the strain region 111′ may extend above and/or below the adjacent second nanostructure 66, and may extend on inner spacer(s) 98 and/or on a gate spacer 92. In some embodiments, a strain region 111′ may have a thickness T1′ in the range of about 4 nm to about 6 nm, though other thicknesses are possible. As shown in FIG. 27, a strain region 111′ may have a convex shape in some embodiments. In some cases, a strain region 111′ may have a shape that is similar to a segment of a circle, a segment of an ellipse, a triangle, or another shape. The strain regions 111′ may be formed of a semiconductor material similar to those described previously for the strain layers 111, and may be formed using similar techniques. For example, the strain regions 111′ may be silicon germanium, arsenic-doped silicon germanium, or the like, and may be formed using an epitaxial growth process. In some embodiments, the epitaxy process may grow the strain regions 111′ laterally from the sidewalls of the second nanostructures 66. In some embodiments, the epitaxy process may be halted before adjacent strain regions 111′ become large enough to merge.

FIG. 28 illustrates the formation of main layers 112 over the strain regions 111′, in accordance with some embodiments. The main layers 112 may be similar to the main layers 112 described previously for FIGS. 16A-16C, and may be formed using similar techniques. For example, the main layers 112 may be silicon phosphide formed using an epitaxial growth process. In this manner, n-type source/drain regions 113′ may be formed comprising strain regions 111′.

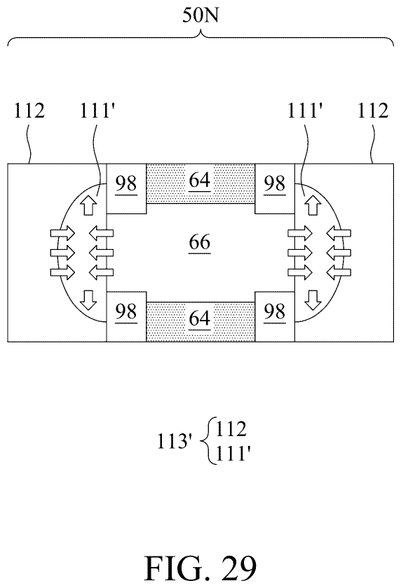

FIG. 29 illustrates a portion of an n-type region 50N comprising strain regions 111′, in accordance with some embodiments. The portion of the n-type region 50N shown in FIG. 29 may be similar to that shown in FIG. 17, except for the strain regions 111′. As shown in FIG. 29 by the vertical arrows, the lattice of the strain regions 111′ can relax in the vertical direction (e.g., in a direction along the sidewalls of the second nanostructures 66). Because the strain regions 111′ have a nonzero Poisson's ratio, a relaxation in the vertical direction results in a contraction in the horizontal direction (e.g., in a direction normal to the sidewalls of the second nanostructures 66) of the strain regions 111′. This horizontal contraction of the strain regions 111′ results in an overall tensile strain of the second nanostructures 66. In this manner, the performance of an n-type nanostructure-FET may be improved while still allowing for the formation of a bottom spacer 110 that reduces leakage.

Embodiments may achieve advantages. The use of strain layers (or strain regions) in epitaxial source/drain regions as described herein can increase the tensile strain of the channel regions of n-type nanostructure-FETs, which can improve device performance. In some cases, the use of strain layers can at least partially compensate for reduced tensile stress exerted by silicon phosphide in some n-type nanostructure-FETs. Further, the strain layers can reduce or eliminate the diffusion of impurities (e.g., phosphorus) into the nanostructures during processing, which can in turn reduce or eliminate the diffusion of germanium into the channel regions. In this manner, device performance may be improved, and the manufacturing process may be improved.

In an embodiment of the present disclosure, a device includes a stack of first nanostructures; a first insulating layer adjacent to the stack of first nanostructures; a first source/drain region over the first insulating layer, wherein the first source/drain region includes a first semiconductor layer extending continuously over the sidewalls of the first nanostructures, wherein the first semiconductor layer is a first semiconductor material and a second semiconductor layer on the first semiconductor layer, wherein the second semiconductor layer is a second semiconductor material different from the first semiconductor material. In an embodiment, the first semiconductor layer exerts tensile stress on the first nanostructures. In an embodiment, the first semiconductor material is silicon germanium. In an embodiment, the first semiconductor material is doped with arsenic. In an embodiment, the second semiconductor material is silicon phosphide. In an embodiment, the first semiconductor layer has a thickness in the range of 4 nm to 6 nm. In an embodiment, the first semiconductor layer physically contacts the first insulating layer. In an embodiment, the first semiconductor layer extends farther from the first insulating layer than a top surface of the stack of first nanostructures.

In an embodiment of the present disclosure, a device includes first nanostructures over a substrate; a semiconductor source/drain layer extending along the sidewalls of the first nanostructures; a semiconductor strain layer extending between the semiconductor source/drain layer and the first nanostructures, wherein the semiconductor strain layer and the semiconductor source/drain layer are different semiconductor materials; and a dielectric layer between the semiconductor strain layer and the substrate. In an embodiment, the device includes a semiconductor region between the dielectric layer and the substrate, wherein the semiconductor region, the semiconductor strain layer, and the semiconductor source/drain layer are different semiconductor materials. In an embodiment, the device includes an inner spacer between two adjacent first nanostructures, wherein the semiconductor strain layer physically contacts the inner spacer. In an embodiment, the device includes a gate spacer over the first nanostructures, wherein the semiconductor strain layer physically contacts the gate spacer. In an embodiment, the semiconductor strain layer is SiGeAs. In an embodiment, the semiconductor strain layer is a continuous layer. In an embodiment, the semiconductor strain layer includes strain regions, wherein each strain region covers a sidewall of a respective first nanostructure. In an embodiment, adjacent strain regions of the semiconductor strain layer are separated by the semiconductor source/drain layer.

In an embodiment of the present disclosure, a method includes forming first nanostructures over a substrate; forming a recess in the substrate adjacent the first nanostructures; depositing a first semiconductor layer in the recess; depositing an insulating layer on the first semiconductor layer; depositing a second semiconductor layer in the recess, wherein the second semiconductor layer extends continuously from a sidewall of the top-most first nanostructure to a sidewall of the bottom-most first nanostructure; and depositing a third semiconductor layer over the first semiconductor layer, wherein the second semiconductor layer and the third semiconductor layer are different semiconductor materials. In an embodiment, a top surface of the first semiconductor layer is lower than the first nanostructures. In an embodiment, a top surface of the insulating layer is lower than the first nanostructures. In an embodiment, the second semiconductor layer includes SiGe.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a stack of nanostructures over a semiconductor fin;
etching the semiconductor fin adjacent the stack of nanostructures to form a recess;
performing a first epitaxial growth process to form a first semiconductor layer at the bottom of the recess;
depositing an insulating layer on the first semiconductor layer;
performing a second epitaxial growth process to form a second semiconductor layer on the insulating layer and on the stack of nanostructures, wherein the second semiconductor layer comprises germanium;
performing a third epitaxial growth process to form a third semiconductor layer on the insulating layer and on the stack of nanostructures, wherein the atomic composition of the third semiconductor layer is different from the atomic composition of the second semiconductor layer; and
forming a gate structure on the stack of nanostructures.

2. The method of claim 1, wherein the second semiconductor layer comprises between 15% and 35% germanium.

3. The method of claim 1, wherein the second semiconductor layer comprises a concentration of arsenic that is in the range of 1×10²¹ atoms/cm³ to 2×10²¹ atoms/cm³.

4. The method of claim 1, wherein the second semiconductor layer has a thickness in the range of 4 nm to 6 nm.

5. The method of claim 1, wherein the third semiconductor layer comprises a concentration of phosphorus that is in the range of 3×10²¹ atoms/cm³ to 4×10²¹ atoms/cm³.

6. The method of claim 1, wherein the second semiconductor layer exerts tensile stress on the nanostructures.

7. The method of claim 1 further comprising forming spacers between adjacent nanostructures, wherein the second semiconductor layer extends on the spacers.

8. The method of claim 1, wherein the third semiconductor layer is n-doped.

9. A method comprising:
forming a first nanostructure and a second nanostructure over a semiconductor substrate;
etching the substrate to form a first recess adjacent the first nanostructure and a second recess adjacent the second nanostructure;
depositing a first semiconductor material in the first recess and in the second recess;
depositing a second semiconductor material on the second nanostructure and on a top surface of the first semiconductor material in the second recess;
depositing a dielectric material on a top surface of the first semiconductor material in the first recess;
depositing a third semiconductor material on the first nanostructure;
depositing a fourth semiconductor material on the third semiconductor material;
forming a first gate stack on the first nanostructure; and
forming a second gate stack on the second nanostructure.

10. The method of claim 9, wherein a concentration of germanium of the third semiconductor material is greater than a concentration of germanium of the fourth semiconductor material.

11. The method of claim 9, wherein a concentration of phosphorus of the fourth semiconductor material is greater than a concentration of phosphorus of the third semiconductor material.

12. The method of claim 9, wherein the second semiconductor material and the fourth semiconductor material are oppositely doped.

13. The method of claim 9, wherein the third semiconductor material directly contacts a top surface of the dielectric material.

14. The method of claim 9, wherein the fourth semiconductor material directly contacts a top surface of the dielectric material.

15. The method of claim 9, wherein the fourth semiconductor material is separated from the first nanostructure by the third material.

16. The method of claim 9, wherein the third semiconductor material exerts tensile stress on the first nanostructure.

17. A device comprising:
a plurality of nanostructures over a semiconductor substrate;
a tensile layer covering each sidewall of the nanostructures of the plurality of nanostructures, wherein the tensile layer comprises silicon and germanium;
a source/drain region on the tensile layer; and
an insulating layer between the source/drain region and the semiconductor substrate.

18. The device of claim 17, wherein a tensile layer covering a sidewall of a nanostructure is separated from the tensile layers covering the sidewalls of adjacent nanostructures.

19. The device of claim 17, further comprising an undoped silicon layer between the insulating layer and the semiconductor substrate.

20. The device of claim 17, wherein the source/drain region is doped with phosphorus.
